(19) United States
(12) Patent Application Publication
(10) Pub. No.: US 2026/0143801 A1
(43) Pub. Date: May 21, 2026

(54) INTEGRATED CIRCUIT INCLUDING MERGED NANOSHEET

(71) Applicant: Samsung Electronics Co., Ltd., Suwon-si (KR)

(72) Inventors: Jungho Do, Suwon-si (KR); Sangjung Jeon, Suwon-si (KR); Geonwoo Nam, Suwon-si (KR); Hyeongyu You, Suwon-si (KR); Minjae Jeong, Suwon-si (KR); Jaehee Cho, Suwon-si (KR)

(21) Appl. No.: 19/264,671

(22) Filed: Jul. 9, 2025

(30) Foreign Application Priority Data
Nov. 21, 2024 (KR) 10-2024-0167749

(51) Int. Cl. H10D 84/85; H01L 23/522; H01L 23/528; H03K 17/687; H10D 30/00; H10D 30/43; H10D 62/10; H10D 62/13; H10D 89/10

(52) U.S. Cl. CPC H10D 84/851; H03K 17/687; H10D 30/43; H10D 30/503; H10D 62/121; H10D 62/151; H10D 84/856; H10D 89/10; H10W 20/42; H10W 20/43; H10W 20/435; H10W 20/498

(57) ABSTRACT

The present disclosure relates to an integrated circuit including a merged nanosheet. An example integrated circuit includes a function cell and a tap cell adjacent to each other in a first direction. The function cell includes a plurality of nanosheets, each of the plurality of nanosheets extending in the first direction and each having a first width in a second direction intersecting the first direction. The tap cell includes a first well having a first conductivity type, at least one merged nanosheet, and at least one first via configured to apply a first supply voltage to the first well. The at least one merged nanosheet extends in the first direction and has a second width that is greater than the first width in the second direction.

### CROSS-REFERENCE TO RELATED APPLICATION

This application claims priority under 35 USC § 119 to Korean Patent Application No. 10-2024-0167749, filed on Nov. 21, 2024, in the Korean Intellectual Property Office, the disclosure of which is incorporated by reference herein in its entirety.

### BACKGROUND

Due to the need for miniaturization, multi-functional, and higher performance of electronic products, high-capacity integrated circuit devices with increased integration are desired. For example, the area of an integrated circuit may be reduced by reducing the cell height and gate line pitch, and the size of the active region, contact, or via may also be reduced. However, this may cause resistance to increase. Therefore, in order to achieve the functions and operating speed for integrated circuit devices, it is desired to design integrated circuit devices by considering the degree of integration and performance.

### SUMMARY

The present disclosure relates to an integrated circuit including a normal nanosheet and a merged nanosheet having different widths.

In some implementations, an integrated circuit includes a function cell and a tap cell adjacent to the function cell in a first direction, wherein the function cell includes a plurality of nanosheets each extending in the first direction and each having a first width in a second direction intersecting the first direction, wherein the tap cell includes a first well having a first conductivity type, at least one merged nanosheet extending in the first direction and having a second width that is greater than the first width in the second direction, and at least one first via configured to apply a first supply voltage to the first well.

In some implementations, an integrated circuit includes a function cell including a plurality of nanosheets each extending in a first direction and each having a first width in a second direction intersecting the first direction and a power switch cell adjacent to the function cell in the first direction, wherein the power switch cell includes a switch transistor between a power line and a virtual power line, the switch transistor includes at least one merged nanosheet extending in the first direction and having a second width that is greater than the first width in the second direction and selectively connects the power line to the virtual power line in response to a control signal to selectively provide a power supply voltage to the function cell.

In some implementations, an integrated circuit includes a function cell and a tap cell adjacent to the function cell in a first direction, wherein the function cell includes a P-type transistor including a first active pattern extending in the first direction and having a first width in a second direction intersecting the first direction and an N-type transistor including a second active pattern extending in the first direction and having the first width in the second direction, and apart from the P-type transistor in the second direction, the tap cell includes at least one merged active pattern extending in the first direction and having a second width that is greater than the first width in the second direction and at least one tap above at least one merged active pattern, wherein the at least one tap includes at least one via configured to apply a supply voltage to a well or substrate.

### BRIEF DESCRIPTION OF THE DRAWINGS

Implementations are more clearly understood from the following detailed description taken in conjunction with the accompanying drawings.

FIGS. 1A, 1B, 1C, 1D, and 1E are example layout diagrams respectively illustrating tap cells.

FIG. 2 is a circuit diagram illustrating an example of an integrated circuit.

FIG. 3 is a schematic diagram illustrating an example of an integrated circuit.

FIG. 4A is an example of a cross-sectional view taken along line I-I′ of FIG. 1C, FIG. 4B is an example of a cross-sectional view taken along line II-II′ of FIG. 1C, and FIG. 4C is an example of a cross-sectional view taken along line III-III′ of FIG. 1C;

FIG. 5A is an example of a cross-sectional view taken along line I-I′ of FIG. 1C, FIG. 5B is an example of a cross-sectional view taken along line II-II′ of FIG. 1C, and FIG. 5C is an example of a cross-sectional view taken along line III-III′ of FIG. 1C;

FIG. 6A is an example of a cross-sectional view taken along line I-I′ of FIG. 1C, FIG. 6B is an example of a cross-sectional view taken along line II-II′ of FIG. 1C, and FIG. 6C is an example of a cross-sectional view taken along line III-III′ of FIG. 1C;

FIG. 7A is an example of a cross-sectional view taken along line I-I′ of FIG. 1C, FIG. 7B is an example of a cross-sectional view taken along line II-II′ of FIG. 1C, and FIG. 7C is an example of a cross-sectional view taken along line III-III′ of FIG. 1C;

FIGS. 8A, 8B, and 8C are plan views respectively illustrating example integrated circuits.

FIGS. 9A, 9B, and 9C are plan views respectively illustrating example integrated circuits.

FIGS. 10A and 10B are layout diagrams illustrating example tap cells.

FIGS. 11A and 11B illustrate example devices, respectively;

FIGS. 12A and 12B are layout diagrams illustrating an example of a tap cell.

FIGS. 13A and 13B are layout diagrams illustrating example tap cells.

FIGS. 14A and 14B are layout diagrams illustrating example tap cells.

FIG. 15A is an example of a cross-sectional view taken along line IV-IV′ of FIG. 14B, and FIG. 15B is an example of a cross-sectional view taken along line V-V′ of FIG. 14B;

FIGS. 16A and 16B are layout diagrams illustrating example tap cells.

FIGS. 17A, 17B, 17C, and 17D are layout diagrams illustrating example tap cells.

FIGS. 18A, 18B, 18C, and 18D are layout diagrams illustrating example tap cells.

FIGS. 19A, 19B, 19C, and 19D are layout diagrams illustrating example tap cells.

FIG. 20 is a layout diagram illustrating an example of an integrated circuit.

FIGS. 21A and 21B are layout diagrams illustrating an example of a power switch cell.

FIGS. 22A and 22B are circuit diagrams respectively illustrating example integrated circuits.

FIG. 23 is a schematic diagram illustrating an example of an integrated circuit.

FIGS. 24A and 24B are layout diagrams illustrating example power switch cells.

FIGS. 25A and 25B are schematic diagrams respectively illustrating example integrated circuits.

FIG. 26 is a flowchart illustrating an example of a method of manufacturing an integrated circuit.

### DETAILED DESCRIPTION

Hereinafter, implementations are described in detail with reference to the accompanying drawings. The same reference numerals are used for identical components in the drawing, and redundant descriptions thereof are omitted.

Herein, an X-axis direction may be referred to as a first direction, a Y-axis direction may be referred to as a second direction, and a Z-axis direction may be referred to as a vertical direction. A plane formed by the X-axis and the Y-axis may be referred to as a horizontal plane, a component placed in a +Z-axis direction relative to other components may be referred to as being located on another component, and a component placed in a −Z-axis direction relative to other components may be referred to as being located below other components.

An integrated circuit may be designed by arranging a plurality of standard cells. The standard cell is a unit of layout of an integrated circuit and may be referred to as a “cell”. The standard cell may be designed to include a plurality of transistors to perform a predefined function. Standard cells are designed and verified in advance and registered in a standard cell library, and integrated circuits may be designed by performing logic design, placement, and routing by combining standard cells using computer-aided design.

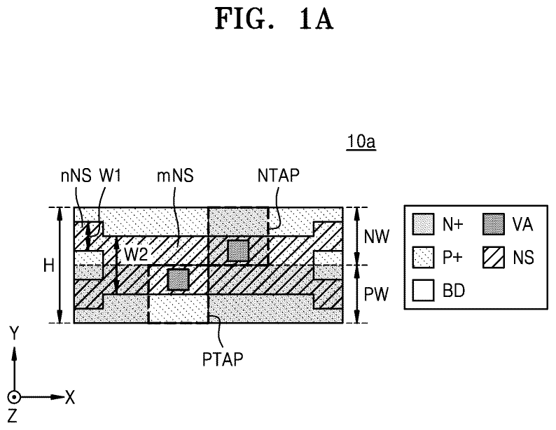

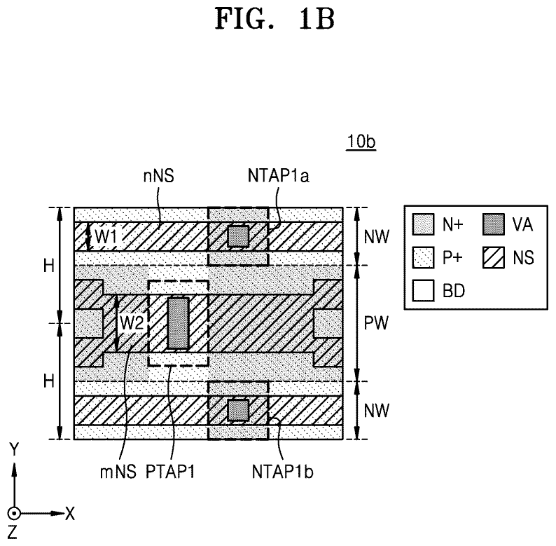

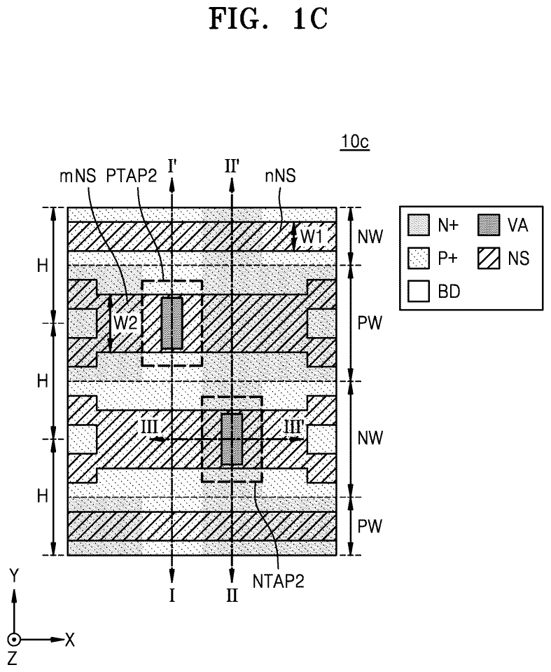

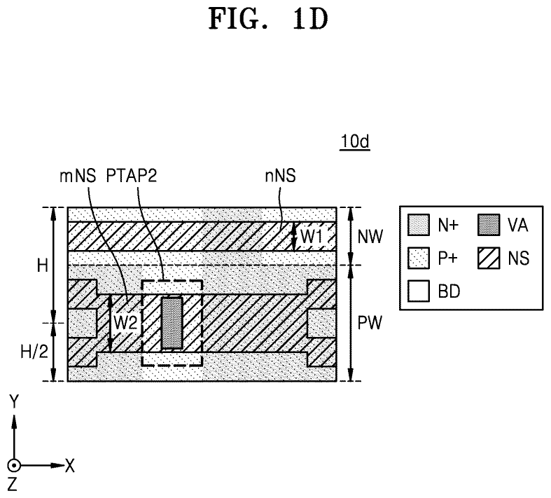

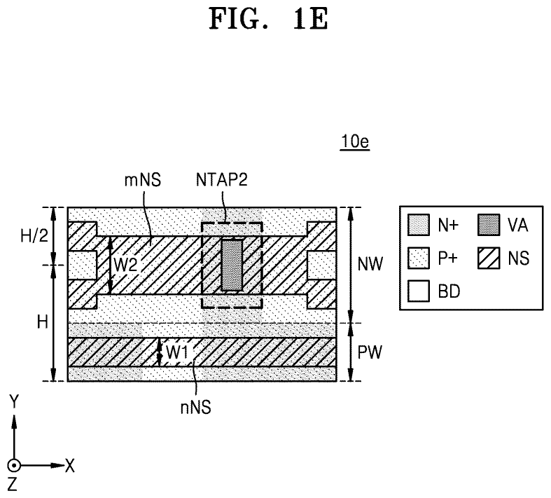

FIG. 1A is a layout diagram illustrating an example of a tap cell 10a.

Referring to FIG. 1A, the tap cell 10a may be defined by a cell boundary BD. The tap cell 10a may be implemented as a ‘single height cell’ having a first cell height H in the second direction Y. The tap cell 10a may include a first well NW having a first conductivity type and a second well PW having a second conductivity type. For example, the first well NW may be a region doped with N-type impurities on a substrate, and the second well PW may be a substrate doped with P-type impurities. However, the present disclosure is not limited thereto, and the second well PW may be a region doped with P-type impurities on the substrate. Hereinafter, the first well NW is referred to as N well NW, and the second well PW is referred to as P well PW. In addition, hereinafter, it is described that the first conductivity type is N-type and the second conductivity type is P-type.

The tap cell 10a may further include first impurity regions doped with impurities having the first conductivity type and second impurity regions doped with impurities having the second conductivity type. Here, an impurity concentration of the first impurity region may be higher than an impurity concentration of the N well PW, and an impurity concentration of the second impurity region may be higher than an impurity concentration of the P well PW. At least one of the first and second impurity regions may have a jog pattern, for example, an L-shaped pattern. For example, the first impurity regions may include N+ regions N+ placed above a portion of the N well NW and the P well PW, and the second impurity regions may include P+ regions P+ placed above the other portion of the N well NW and the P well PW.

The tap cell 10a may be used to prevent a latch-up problem in the design of a complementary metal oxide semiconductor (CMOS) integrated circuit and may be referred to as a “well tap cell” or a “substrate tap cell”. To prevent the latch-up problem, in the tap cell 10a, the N well NW may be connected to a first supply voltage, for example, a power supply voltage VDD, and the P-type substrate or P well PW may be connected to a second supply voltage, for example, a ground voltage VSS. Without a logical function, the tap cell 10a may be referred to as a dummy cell or a physical cell. The above description of the tap cell 10a may be applied to various tap cells provided herein.

As semiconductor process technology has advanced and an integrated circuit has become smaller, the cell height of standard cells has decreased, which in turn an active region within the standard cell has also become smaller. To prevent latch-up under high voltage conditions, it is necessary to arrange a greater number of tap cells in the integrated circuit. Due to this, a placement ratio of tap cells within logic blocks of the integrated circuit has increased, so it is necessary to secure area competitiveness for tap cells. According to the present disclosure, the number of active patterns arranged in the second direction Y in the tap cell 10a may be reduced compared to adjacent function cells. Accordingly, the frequency of occurrence of a space between active patterns may be reduced, and by utilizing the reduced space as a width of the active patterns, a wide active pattern in the second direction Y may be implemented.

In some implementations, each active pattern may include a nanosheet or a nanosheet stack. The nanosheet stack may include a plurality of nanosheets spaced in the vertical direction Z. A function cell arranged adjacent to the tap cell 10a in the first direction X may include nanosheets or normal nanosheets each having a first width W1 in the second direction Y, and the tap cell 10a may include a wide nanosheet or a merged nanosheet having a second width W2 that is greater than the first width W1 in the second direction Y. In this manner, latch-up defects may be reduced and the area competitiveness of the tap cell 10a may be secured.

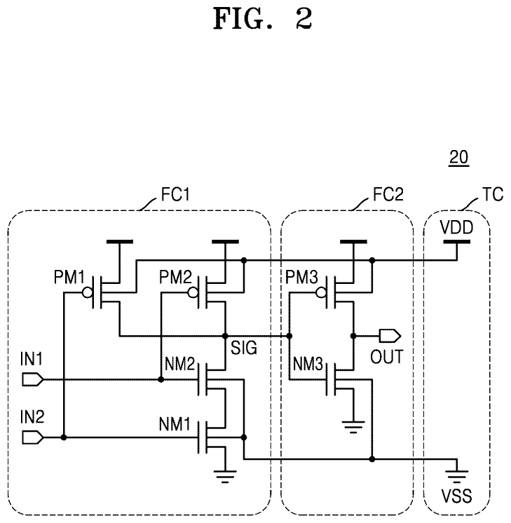

In some implementations, the tap cell 10a may include active patterns, for example, nanosheets NS, each extending in the first direction X. The nanosheets NS may include normal nanosheets nNS each having the first width W1 in the second direction Y and a merged nanosheet mNS having the second width W2 that is greater than the first width W1 in the second direction Y. For example, the second width W2 may be twice or more of the first width W1. For example, the normal nanosheets nNS may be arranged above the N well NW or the P well PW, and the merged nanosheet mNS may be arranged above the N well NW and the P well PW. For example, the normal nanosheets nNS may be connected to a function cell (e.g., FC1 or FC2 in FIG. 2) adjacent to the tap cell 10a in the first direction X. The function cell may include a plurality of active patterns, for example, a plurality of nanosheets, each having the first width W1 in the second direction Y.

The tap cell 10a may further include vias VA. For example, the via VA placed above the N well NW and the first impurity region N+ may receive the first supply voltage, for example, the power supply voltage VDD, and the via VA may constitute a well tap or first tap NTAP that provides the first supply voltage to the first impurity region N+ and the N well NW. For example, the via VA placed above the P well PW and the second impurity region P+ may receive the second supply voltage, for example, the ground voltage VSS, and the via VA may constitute a substrate tap or second tap PTAP that provides the second supply voltage to the second impurity region P+ and the P well PW.

FIG. 1B is a layout diagram illustrating an example of a tap cell 10b.

Referring to FIG. 1B, the tap cell 10b may include N wells NW, P wells PW, first impurity regions N+, and second impurity regions P+ and may be defined by the cell boundary BD. The tap cell 10b may be implemented as a ‘double height cell’ having a second cell height (2×H) in the second direction Y. The tap cell 10b corresponds to a modified example of the tap cell 10a of FIG. 1A, and the description given above with reference to FIG. 1A may also be applied to the present implementation.

The tap cell 10b may further include active patterns, for example, nanosheets NS, each extending in the first direction X. The nanosheets NS may include normal nanosheets nNS each having the first width W1 in the second direction Y and a merged nanosheet mNS having the second width W2 that is greater than the first width W1 in the second direction Y. For example, normal nanosheets nNS may be arranged above the N well NW or the P well PW, and the merged nanosheet mNS may be arranged above the P well PW. For example, the normal nanosheets nNS may be connected to a function cell (e.g., FC1 or FC2 in FIG. 2) adjacent to the tap cell 10b in the first direction X. The function cell may include the active patterns, for example, the nanosheets, each having the first width W1 in the second direction Y.

Due to the development of semiconductor process technology, a space between gate lines, i.e., a contacted poly pitch (CPP), may be reduced, and accordingly, the size of a contact between gate lines, i.e., a source/drain contact, may be reduced and the size of a via above the contact may also be reduced. Accordingly, the size of vias and contacts that receive the power supply voltage or ground voltage in the tap cell may be reduced, which may increase resistance. However, by arranging the merged nanosheet mNS in a central region of the tap cell 10b and arranging an N tap and/or a P tap above the merged nanosheet mNS, the size of the N tap and/or the P tap may be increased, thereby securing the size of the via and contact and reducing the resistance.

In some implementations, the tap cell 10b may further include vias VA. For example, vias VA arranged above the N well NW and the first impurity region N+ may receive the first supply voltage, for example, the power supply voltage VDD, and the vias VA may constitute first taps NTAP1a and NTAP1b that provide the first supply voltage to the first impurity region N+ and the N well NW, respectively. For example, the via VA placed above the P well PW and the second impurity region P+ may receive the second supply voltage, for example, the ground voltage VSS, and the via VA may constitute a second tap PTAP1 that provides the second supply voltage to the second impurity region P+ and the P well PW.

Here, the second tap PTAP1 may be placed above the merged nanosheet mNS and may be implemented with a greater size than the first taps NTAP1a and NTAP1b. In some implementations, the second tap PTAP1 may include a long via extending in the second direction Y. In this manner, by increasing the size of the second tap PTAP1, the region for applying voltage to the P well PW in the tap cell 10b may be increased, thereby reducing the resistance. In some implementations, the second tap PTAP1 may include a plurality of vias VA arranged in the second direction Y. Here, the number and/or size of the vias of each of the first taps NTAP1a and NTAP1b may be different from the number and/or size of the vias of the second tap PTAP1.

The normal nanosheets nNS may overlap the cell boundary BD, and the merged nanosheet mNS may be arranged within the tap cell 10b. In a region adjacent to the cell boundary BD, i.e., an edge region of the tap cell 10b, the tap cell 10b may include four nanosheets NS adjacent in the second direction Y so that three spaces may exist between the nanosheets NS. In addition, in the central region of the tap cell 10b, the tap cell 10b includes three nanosheets NS adjacent in the second direction so that two spaces may exist between the nanosheets NS. In this manner, the occurrence frequency of nanosheet spaces in the central region of the tap cell 10b may be reduced, and the second width W2 of the merged nanosheet mNS may be increased. In addition, the size of the second tap PTAP1 above the merged nanosheet mNS may be increased, thereby increasing the number and/or length of vias VA of the second tap PTAP1. Accordingly, the resistance within the tap cell 10b may be reduced, latch-up defects of the integrated circuit including the tap cell 10b may be reduced, and the area competitiveness of the tap cells may be enhanced.

FIG. 1C is a layout diagram illustrating an example of a tap cell 10c.

Referring to FIG. 1C, the tap cell 10c may include N wells NW, P wells PW, first impurity regions N+, and second impurity regions P+ and may be defined by the cell boundary BD. The tap cell 10c may be implemented as a ‘triple height cell’ having a third cell height (3×H) in the second direction Y. The tap cell 10c corresponds to a modified example of the tap cell 10a of FIG. 1A, and the description given above with reference to FIG. 1A may also be applied to the present implementation.

The tap cell 10c may further include active patterns, for example, nanosheets NS, each extending in the first direction X. The nanosheets NS may include normal nanosheets nNS each having the first width W1 in the second direction Y and merged nanosheets mNS each having the second width W2 that is greater than the first width W1 in the second direction Y. For example, the normal nanosheets nNS may be connected to a function cell (e.g., FC1 or FC2 in FIG. 2) adjacent to the tap cell 10c in the first direction X. The function cell may include the active patterns, for example, the nanosheets, each having the first width W1 in the second direction Y.

The tap cell 10c may further include vias VA. For example, a via VA placed above the N well NW and the first impurity region N+ may receive the first supply voltage, for example, the power supply voltage VDD, and the via VA may constitute a first tap NTAP2 that provides the first supply voltage to the first impurity region N+ and the N well NW. For example, the via VA placed above the P well PW and the second impurity region P+ may receive the second supply voltage, for example, the ground voltage VSS, and the via VA may constitute a second tap PTAP2 that provides the second supply voltage to the second impurity region P+ and the P well PW. For example, in some implementations, the first and second taps NTAP2 and PTAP2 may each include a long via extending in the second direction Y. In some implementations, the first and second taps NTAP2 and PTAP2 may each include a plurality of vias VA arranged in the second direction Y. In this manner, by increasing the size of the first and second taps NTAP2 and PTAP2, the region for applying voltage to the N well NW and the P well PW in the tap cell 10c may be increased, thereby reducing the resistance.

The normal nanosheets nNS may overlap the cell boundary BD, and the merged nanosheets mNS may be arranged within the tap cell 10c. The tap cell 10c includes six nanosheets NS adjacent in the second direction Y in a region adjacent to the cell boundary BD, i.e., an edge region of the tap cell 10c, so that five spaces may exist between the nanosheets NS. Furthermore, the tap cell 10c includes four nanosheets NS adjacent in the second direction in the central region of the tap cell 10c so that three spaces may exist between the nanosheets NS. In this manner, the frequency of occurrence of nanosheet gaps in the central region of the tap cell 10c may be reduced, and the second width W2 of the merged nanosheet mNS may be increased. In addition, the size of each of the first and second taps NTAP2 and PTAP2 above the merged nanosheet mNS may be increased, thereby increasing the number and/or length of the vias VA of each of the first and second taps NTAP2 and PTAP2. Accordingly, the resistance within the tap cell 10c may be reduced, latch-up defects of the integrated circuit including the tap cell 10c may be reduced, and the area competitiveness of the tap cells may be enhanced.

FIG. 1D is a layout diagram illustrating an example of a tap cell 10d.

Referring to FIG. 1D, the tap cell 10d may include N wells NW, P wells PW, first impurity regions N+, and second impurity regions P+ and may be defined by the cell boundary BD. The tap cell 10d may have a fourth cell height (1.5×H) in the second direction Y. The tap cell 10d corresponds to a modified example of the tap cell 10c of FIG. 1C, and the description given above with reference to FIG. 1C may also be applied to the present implementation.

The tap cell 10d may further include active patterns, for example, nanosheets NS, each extending in the first direction X. The nanosheets NS may include a normal nanosheet nNS having the first width W1 in the second direction Y and a merged nanosheet mNS having the second width W2 that is greater than the first width W1 in the second direction Y. The tap cell 10d may further include a via VA. For example, the via VA placed above the P well PW and the second impurity region P+ may receive the second supply voltage, for example, the ground voltage VSS, and the via VA may constitute a second tap PTAP2 that provides the second supply voltage to the second impurity region P+ and the P well PW. In some implementations, the second tap PTAP2 may include a long via extending in the second direction Y. In some implementations, the second tap PTAP2 may include a plurality of vias VA arranged in the second direction Y.

FIG. 1E is a layout diagram illustrating an example of a tap cell 10e.

Referring to FIG. 1E, the tap cell 10e may include N wells NW, P wells PW, first impurity regions N+, and second impurity regions P+ and may be defined by the cell boundary BD. The tap cell 10e may have a fourth cell height (1.5×H) in the second direction Y. The tap cell 10e corresponds to a modified example of the tap cell 10c of FIG. 1C, and the description given above with reference to FIG. 1C may also be applied to the present implementation.

The tap cell 10e may further include active patterns, for example, nanosheets NS, each extending in the first direction X. The nanosheets NS may include a normal nanosheet nNS having the first width W1 in the second direction Y and a merged nanosheet mNS having the second width W2 that is greater than the first width W1 in the second direction Y. The tap cell 10e may further include a via VA. For example, a via VA placed above the N well NW and the first impurity region N+ may receive the first supply voltage, for example, the power supply voltage VDD, and the via VA may constitute a first tap NTAP2 that provides the first supply voltage to the first impurity region N+ and the N well NW. In some implementations, the first tap NTAP2 may include a long via extending in the second direction Y. In some implementations, the first tap NTAP2 may include a plurality of vias VA arranged in the second direction Y.

FIG. 2 is a circuit diagram illustrating an example of an integrated circuit 20.

Referring to FIG. 2, the integrated circuit 20 may include a first function cell FC1, a second function cell FC2, and a tap cell TC. For example, the first function cell FC1 may include a NAND gate cell including PMOS transistors PM1 and PM2 and NMOS transistors NM1 and NM2. For example, the second function cell FC2 may be an inverter cell including a PMOS transistor PM3 and an NMOS transistor NM3. The first function cell FC1 may generate a signal SIG from the first and second input signals IN1 and IN2, and the second function cell FC2 may generate an output signal OUT from the signal SIG.

The tap cell TC may be connected to the first and second function cells FC1 and FC2 and may provide the first supply voltage, for example, the power supply voltage VDD, and the second supply voltage, for example, the ground voltage VSS, to the first and second function cells FC1 and FC2. In some implementations, the tap cell TC may include an N tap or a first tap (e.g., NTAP of FIG. 1A, NTAP1a and NTAP1b of FIG. 1B, or NTAP2 of FIGS. 1C and 1E) that provides the power supply voltage VDD to the body, i.e., the N well (e.g., NW of FIGS. 1A to 1E), of each of the PMOS transistors PM1, PM2, and PM3. In addition, the tap cell TC may include a P-tap or a second tap (e.g., PTAP of FIG. 1A, PTAP1 of FIG. 1B, or PTAP2 of FIGS. 1C and 1D) that provides the ground voltage VSS to the body of each of the NMOS transistors NM1, NM2, and NM3, i.e., a P-type substrate or P well (e.g., PW of FIGS. 1A to 1E).

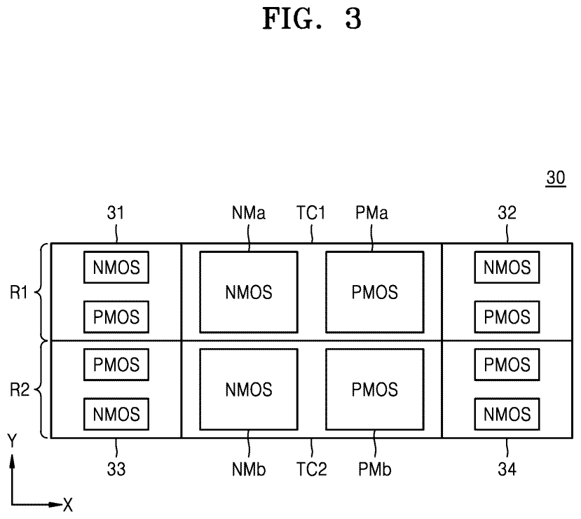

FIG. 3 is a schematic diagram illustrating an example of an integrated circuit 30.

Referring to FIG. 3, the integrated circuit 30 may include first to fourth function cells 31 to 34 and first and second tap cells TC1 and TC2. For example, the first function cell 31, the first tap cell TC1, and the second function cell 32 may be arranged in the first direction X in a first row R1, and the third function cell 33, the second tap cell TC2, and the fourth function cell 34 may be arranged in the first direction X in a second row R2. For example, at least one of the first to fourth function cells 33 and 34 may correspond to the first or second function cell FC1 or FC2 of FIG. 2.

Each of the first and second function cells 31 and 32 may include an N-type transistor, i.e., an NMOS transistor, and a P-type transistor, i.e., a PMOS transistor, arranged in the second direction Y, and the NMOS transistor and the PMOS transistor may each include a normal nanosheet (e.g., nNS of FIG. 1A) having the first width (e.g., W1 of FIG. 1A). In addition, the first tap cell TC1 may include an NMOS transistor NMa adjacent to the first function cell 31 and a PMOS transistor PMa adjacent to the second function cell 32, and here, the NMOS transistor NMa and the PMOS transistor PMa may each include a merged nanosheet (e.g., mNS of FIG. 1) having the second width (e.g., W2 of FIG. 1A) that is greater than the first width W1.

Similarly, each of the third and fourth function cells 33 and 34 may include a PMOS transistor and an NMOS transistor arranged in the second direction Y, and the PMOS transistor and the NMOS transistor may each include a normal nanosheet (e.g., nNS of FIG. 1A) having the first width W1. In addition, the second tap cell TC2 may include an NMOS transistor NMb adjacent to the third function cell 33 and a PMOS transistor PMb adjacent to the fourth function cell 34, and here, the NMOS transistor NMb and the PMOS transistor PMb may each include a merged nanosheet (e.g., mNS of FIG. 1) having the second width W2 that is greater than the first width W1.

Thus, each of the first to fourth function cells 31 to 34 may include a plurality of nanosheets each having the first width W1, and each of the first and second tap cells TC1 and TC2 may include at least one merged nanosheet having the second width W2. In this manner, each of the first and second tap cells TC1 and TC2 includes a wider merged nanosheet than the first to fourth function cells 31 to 34, thereby reducing the resistance within the tap cell to reduce latch-up defects and secure the area competitiveness of the tap cells. In some implementations, a structure in which two or more nanosheets are combined may be referred to as a ‘hyper cell’, and a tap cell having such a structure may be referred to as a ‘hyper tap cell’.

As described above, the integrated circuit 30 may include the function cells 31 to 34 and tap cells TC1 and TC2 adjacent to each other in the first direction X. Each of the function cells 31 to 34 may include a P-type transistor (e.g., PMOS) including a first active pattern extending in the first direction X and having the first width in the second direction Y and an N-type transistor (e.g., NMOS) including a second active pattern extending in the first direction X and having the first width in the second direction Y, and here, the P-type transistor and the N-type transistor may be apart from each other in the second direction Y. Each of the tap cells TC1 and TC2 may include at least one merged active pattern extending in the first direction X and having the second width that is greater than the first width in the second direction Y and at least one tap on top of the at least one merged active pattern, and here, the at least one tap may include at least one via configured to apply a supply voltage to a well or a substrate.

In some implementations, each of the tap cells TC1 and TC2 may further include a plurality of active patterns each extending in the first direction X and each having the first width in the second direction Y. In some implementations, each of the plurality of active patterns may include a nanosheet stack, and the nanosheet stack may include a plurality of normal nanosheets that are apart from each other in the vertical direction and having the first width in the second direction Y. In some implementations, at least one merged active pattern may include a merged nanosheet stack, and here, the merged nanosheet stack may include a plurality of merged nanosheets that are apart from each other in the vertical direction and having the second width in the second direction Y.

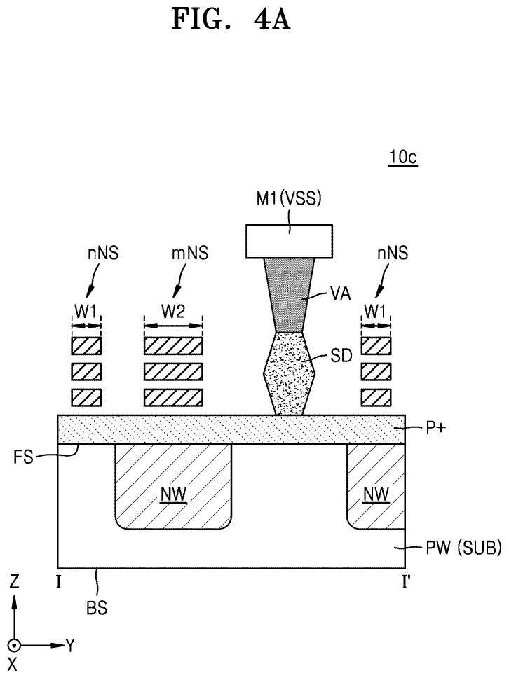

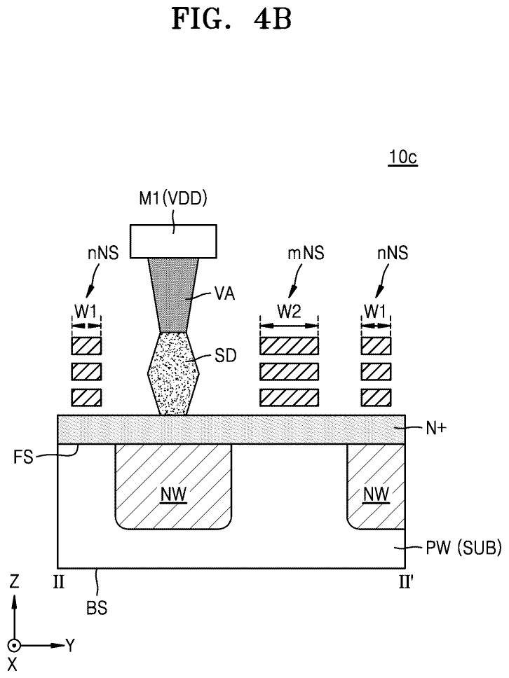

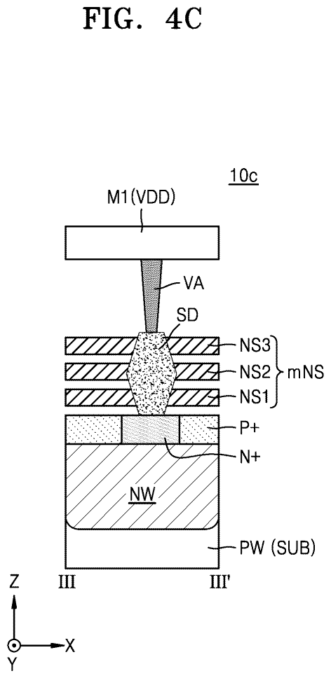

FIG. 4A is an example of a cross-sectional view taken along line I-I′ of FIG. 1C, FIG. 4B is an example of a cross-sectional view taken along line II-II′ of FIG. 1C, and FIG. 4C is an example of a cross-sectional view taken along line III-III′ of FIG. 1C. FIGS. 4A to 4C illustrate examples of nanosheets formed on an active region. For example, a multi-bridge channel field effect transistor (MBCFET) in which a plurality of nanosheets are stacked on an active region and a gate line surrounds the plurality of nanosheets may be formed. However, the integrated circuit according to the present disclosure is not limited to the illustration in FIGS. 4A to 4C. For example, a gate-all-around field effect transistor (GAAFET) in which nanowires formed on the active region are surrounded by gate lines may be formed.

Referring to FIG. 1C and FIG. 4A to FIG. 4C together, the tap cell 10c may be placed on the substrate SUB extending in the first direction X and the second direction Y. The substrate SUB may include a semiconductor material, such as silicon, germanium, silicon-germanium, or a group III-V compound, such as GaAs, AlGaAs, InAs, InGaAs, InSb, GaSb, InGaSb, InP, GaP, InGaP, InN, GaN, InGaN, etc. For example, the substrate SUB may be a silicon-on-insulator (SOI) substrate or a germanium-on-insulator (GOI) substrate. For example, the substrate SUB may be a P-type substrate doped with P-type impurities. Herein, the substrate SUB may correspond to a P well PW. However, the present disclosure is not limited thereto, and the P well PW extending in the first direction X may be placed within the substrate SUB. The substrate SUB may have a front side FS and a back side BS facing each other.

The active regions may be defined by a device isolation film (e.g., shallow trench isolation) on the substrate SUB. For example, the active regions may include an N well NW doped with N-type impurities, in which a P-type transistor, for example, a P-type GAA transistor, may be formed. For example, the active regions may include the P well PW doped with P-type impurities, in which an N-type transistor, for example, an N-type GAA transistor, may be formed. Each of the first and second taps NTAP2 and PTAP2 included in the tap cell 10c may include the via VA on the source/drain SD, and the via VA may receive the power supply voltage VDD or the ground voltage VSS from a first metal layer M1 placed above the front side FS of the substrate SUB.

A first impurity region N+ and a second impurity region P+ may be arranged on the front side FS of the substrate SUB. Active patterns, for example, nanosheets NS, may be formed above the first and second impurity regions N+ and P+. The nanosheets NS may function as channels of the transistors. The nanosheets NS may include normal nanosheets nNS and merged nanosheets mNS. Each of the normal nanosheets nNS may have the first width W1 in the second direction Y, and each of the merged nanosheets mNS may have the second width W2 in the second direction Y. For example, the merged nanosheet mNS may include nanosheets NS1 to NS3 apart from each other in the vertical direction Z.

The source/drains SD may be arranged above the first and second impurity regions N+ and P+, the via VA may be placed on the source/drain SD, and the first metal layer M1 may be placed above the via VA. The first tap NTAP2 may include the via VA above the first impurity region N+ and may provide the power supply voltage VDD received from the first metal layer M1 to the first impurity region N+ and the N well NW. The second tap PTAP2 may include the via VA above the second impurity region P+ and may provide the ground voltage VSS received from the first metal layer M1 to the second impurity region P+ and the P well PW.

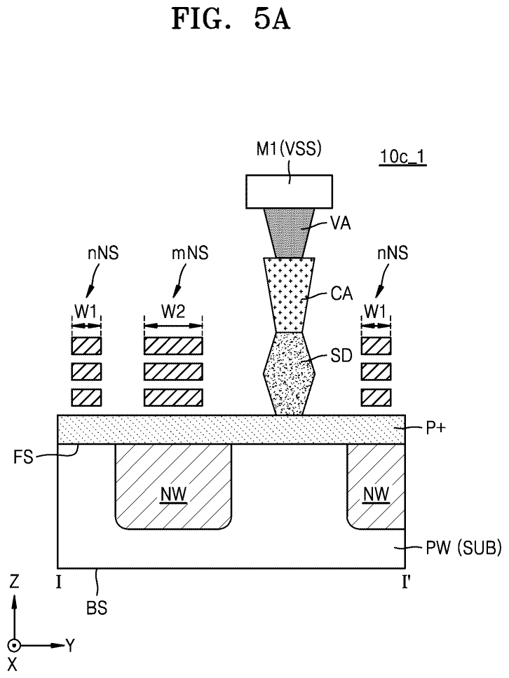

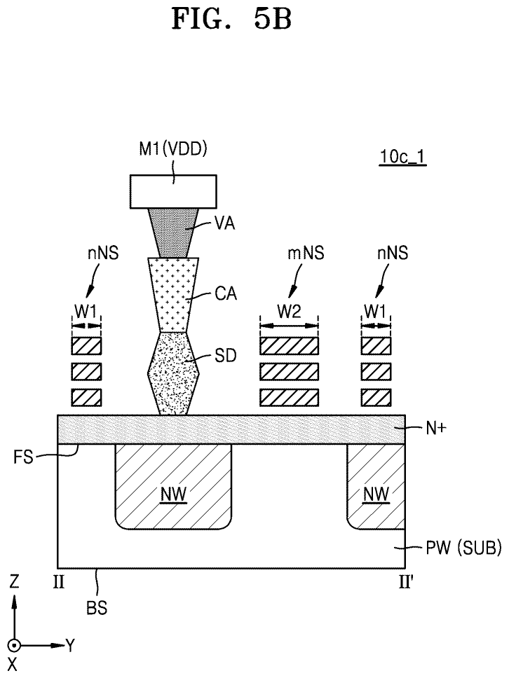

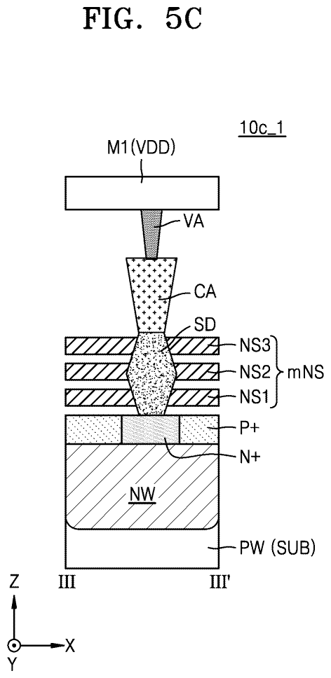

FIG. 5A is an example of a cross-sectional view taken along line I-I′ of FIG. 1C, FIG. 5B is an example of a cross-sectional view taken along line II-II′ of FIG. 1C, and FIG. 5C is an example of a cross-sectional view taken along line III-III′ of FIG. 1C.

Referring to FIGS. 5A to 5C, the first and second taps NTAP2 and PTAP2 included in a tap cell 10c_1 may include a contact CA and the via VA on the source/drain SD, and the via VA may receive the power supply voltage VDD or the ground voltage VSS from the first metal layer M1 placed above the front side FS of the substrate SUB. The tap cell 10c_1 corresponds to a modified example of the tap cell 10c of FIGS. 4A to 4C, and a redundant description is omitted.

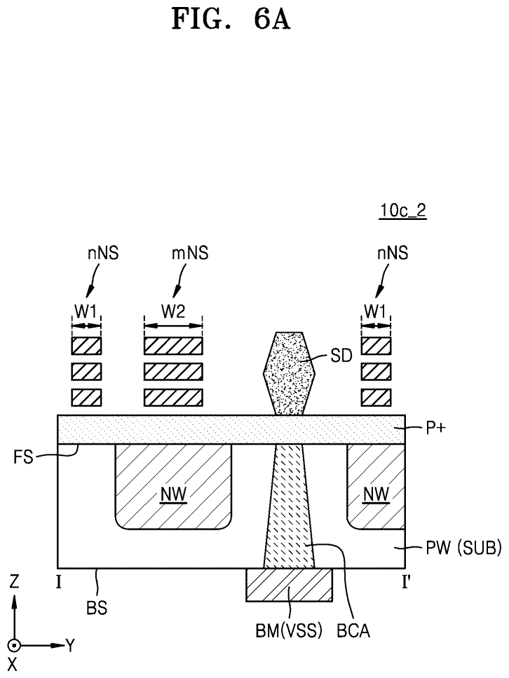

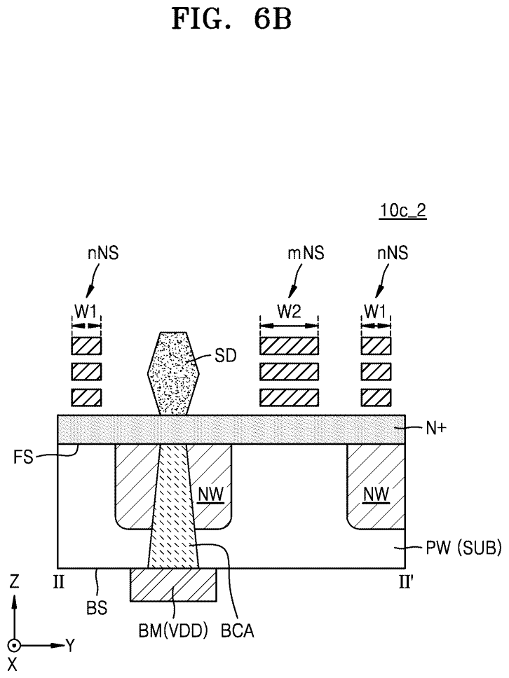

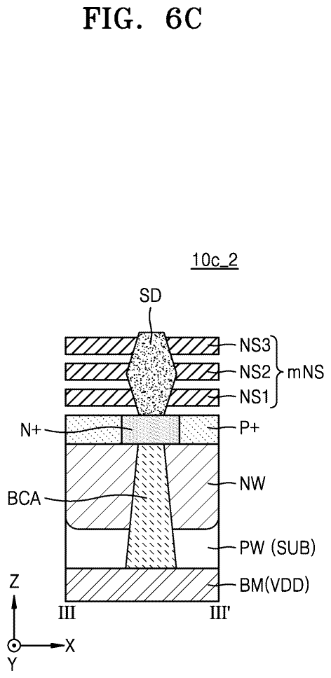

FIG. 6A is an example of a cross-sectional view taken along line I-I′ of FIG. 1C, FIG. 6B is an example of a cross-sectional view taken along line II-II′ of FIG. 1C, and FIG. 6C is an example of a cross-sectional view taken along line III-III′ of FIG. 1C.

Referring to FIGS. 6A to 6C, the first and second taps NTAP2 and PTAP2 included in a tap cell 10c_2 may include a first back metal layer BM and a back contact BCA. The first back metal layer BM may be placed on the back side BS of the substrate SUB. The back contact BCA is placed on the first back metal layer BM and may penetrate the substrate SUB in the vertical direction Z. Accordingly, the back contact BCA may receive the supply voltage VDD or the ground voltage VSS from the first back metal layer BM. In some implementations, the back contact BCA may be referred to as a back via. The tap cell 10c_2 corresponds to a modified example of the tap cell 10c of FIGS. 4A to 4C, and a redundant description is omitted. For example, the first tap NTAP2 may include the back contact BCA below the first impurity region N+ and may provide the power supply voltage VDD received from the first back metal layer BM to the first impurity region N+. For example, the second tap PTAP2 may include the back contact BCA below the second impurity region P+ and may provide the ground voltage VSS received from the first back metal layer BM to the second impurity region P+.

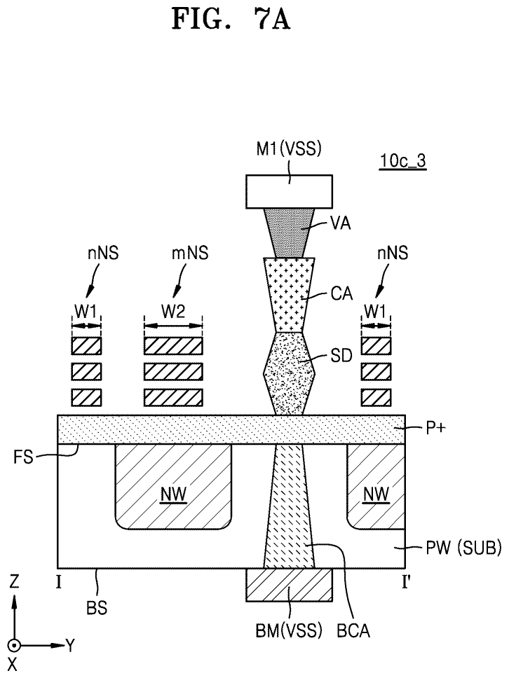

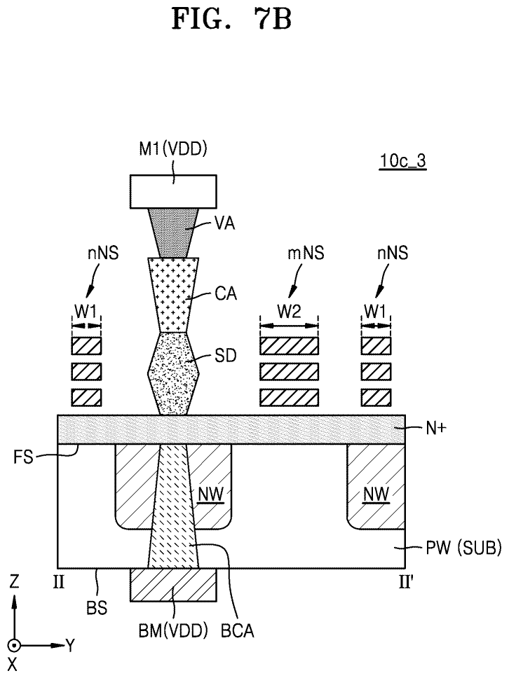

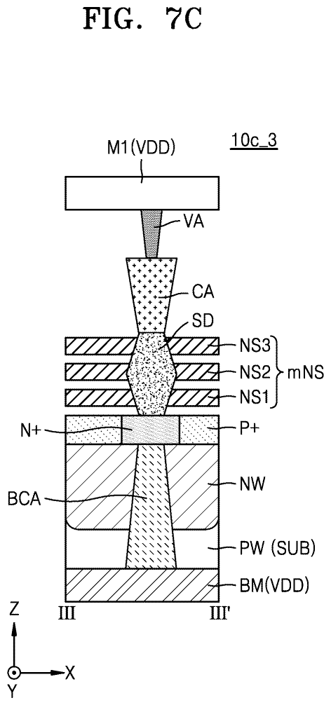

FIG. 7A is an example of a cross-sectional view taken along line I-I′ of FIG. 1C, FIG. 7B is an example of a cross-sectional view taken along line II-II′ of FIG. 1C, and FIG. 7C is an example of a cross-sectional view taken along line III-III′ of FIG. 1C.

Referring to FIGS. 7A to 7C, the first and second taps NTAP2 and PTAP2 included in a tap cell 10c_3 may include the contact CA and the via VA on the source/drain SD and the back contact BCA, the via VA may receive the power supply voltage VDD or the ground voltage VSS from the first metal layer M1 placed above the front side FS of the substrate SUB, and the back contact BCA may receive the power supply voltage VDD or the ground voltage VSS from the first back metal layer BM placed on the back side BS of the substrate SUB. The tap cell 10c_3 corresponds to a modified example of the tap cell 10c of FIGS. 4A to 4C, and a redundant description is omitted.

The first tap NTAP2 may include the via VA above the first impurity region N+ and may provide the power supply voltage VDD received from the first metal layer M1 to the first impurity region N+. In addition, the first tap NTAP2 may further include the back contact BCA below the first impurity region N+ and may provide the power supply voltage VDD received from the first back metal layer BM to the first impurity region N+. Furthermore, the second tap PTAP2 may include the via VA above the second impurity region P+ and may provide the ground voltage VSS received from the first metal layer M1 to the second impurity region P+. In addition, the second tap PTAP2 may further include the back contact BCA below the second impurity region P+ and may provide the ground voltage VSS received from the first back metal layer BM to the second impurity region P+.

As described above, the tap cells 10c_2 and 10c_3 may include a front interconnection layer placed above the front side FS of the substrate SUB and/or a back interconnection layer placed on the back side BS of the substrate SUB, and a power distribution network (PDN) may be implemented using the front interconnection layer and/or the back interconnection layer. Accordingly, some of signals and/or power applied to the integrated circuit may be transmitted through the front interconnection layer, i.e., a front side PDN (FSPDN), and the rest may be transmitted through the back interconnection layer, i.e., a back side PDN (BSPDN). Therefore, according to the present implementation, compared to a structure in which interconnections are arranged only on the front side of the substrate, the routing complexity may be significantly reduced and the length of each interconnection or each via may also be reduced, thereby improving the performance of the integrated circuit.

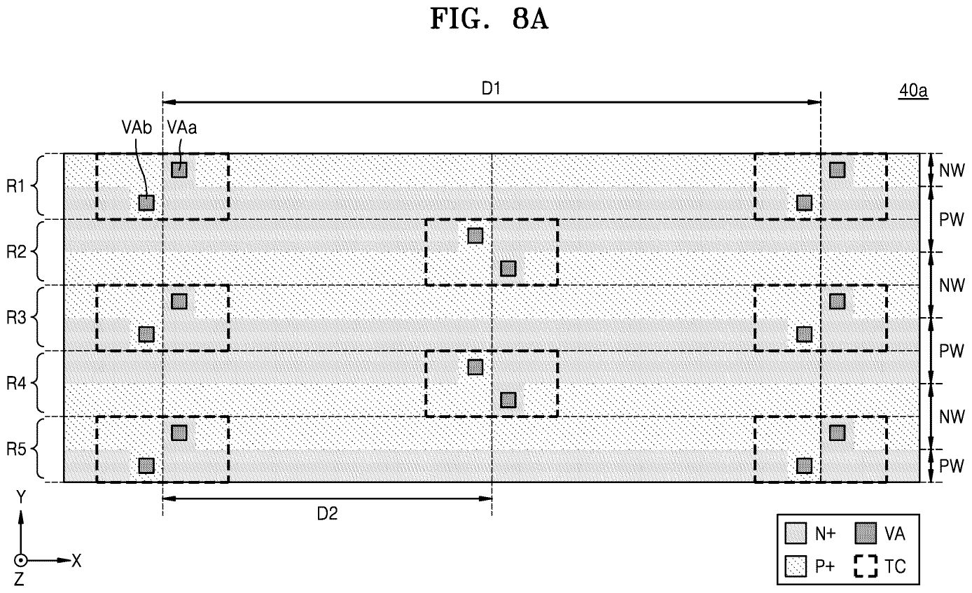

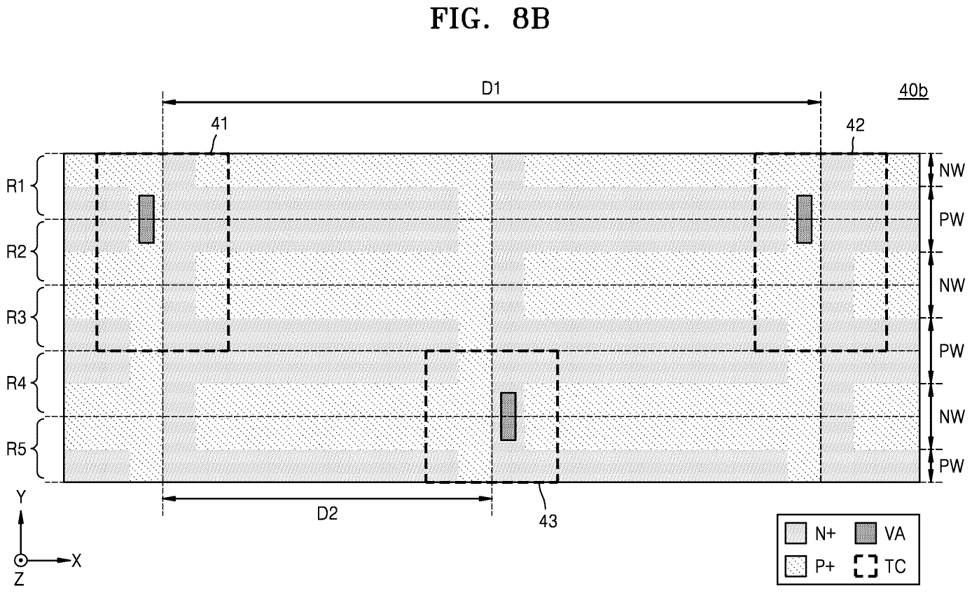

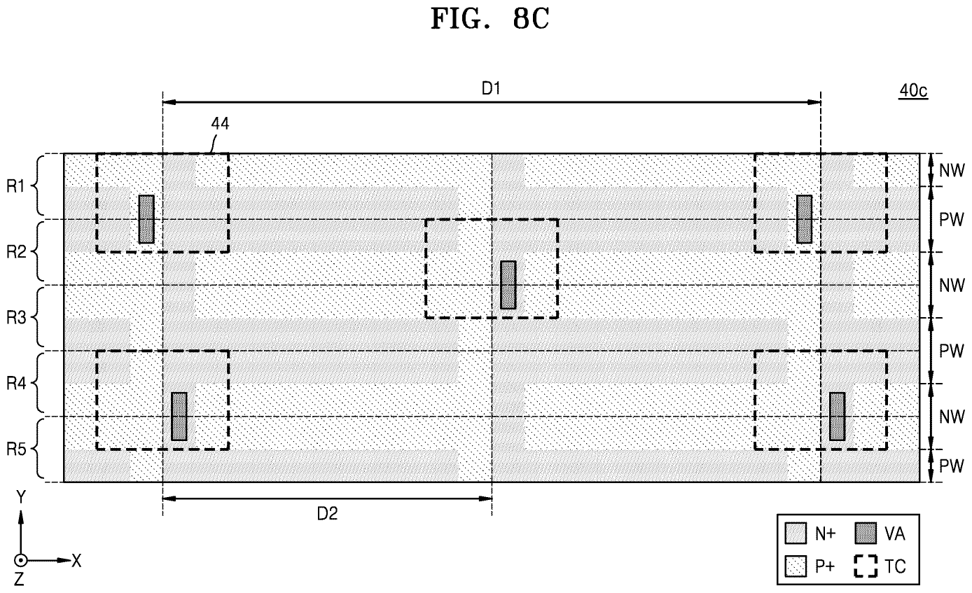

FIG. 8A is a plan view illustrating an example of an integrated circuit 40a.

Referring to FIG. 8A, the integrated circuit 40a may include N wells NW and P wells PW each extending in the first direction X and first and second impurity regions N+ and P+ arranged as jog pattern types or jogging pattern types on the N wells NW and P wells PW. In addition, the integrated circuit 40a may further include a plurality of tap cells TC arranged as staggered types. For example, a distance between the center lines of two tap cells TC arranged in the first row R1 may correspond to a first distance D1. For example, a distance between the center lines of the tap cells TC arranged in the second row R2 and the center lines of the tap cells TC arranged in the first row R1 may correspond to a second distance D2. Here, the first distance D1 may correspond to twice the second distance D2.

For example, each of the tap cells TC may include a merged nanosheet (e.g., mNS of FIGS. 1A to 1E), such as the tap cells 10a to 10e of FIGS. 1A to 1E. In addition, each of the tap cells TC may include vias VA. The power supply voltage VDD may be provided to the first impurity region N+ and the N well NW through vias VAa, and the ground voltage VSS may be provided to the second impurity region P+ and the P well PW through vias VAb. Function cells may be arranged around the tap cells TC, and each function cell may include a plurality of normal nanosheets (e.g., nNS of FIGS. 1A to 1E).

FIG. 8B is a plan view illustrating an example of an integrated circuit 40b.

Referring to FIG. 8B, the integrated circuit 40b corresponds to a modified example of the integrated circuit 40a of FIG. 8A, and the following description focuses on the differences from FIG. 8A. The integrated circuit 40b may include tap cells 41 and 42 arranged across first to third rows R1 to R3 and a tap cell 43 placed across fourth and fifth rows R4 and R5. The tap cells 41 and 42 may correspond to triple height cells and may include, for example, the tap cell 10c of FIG. 1C. The tap cell 43 may correspond to a double height cell and may include, for example, the tap cell 10b of FIG. 1B. Here, the tap cells 41 to 43 may be arranged as staggered types.

FIG. 8C is a plan view illustrating an example of an integrated circuit 40c.

Referring to FIG. 8C, the integrated circuit 40c corresponds to a modified example of the integrated circuit 40a of FIG. 8A, and the following description focuses on the differences from FIG. 8A. The integrated circuit 40c may include tap cells 44 arranged across 1.5 rows. For example, the tap cells 44 may include the tap cells 10d of FIG. 1D and/or the tap cells 10e of FIG. 1E. Here, the tap cells 44 may be arranged as staggered types.

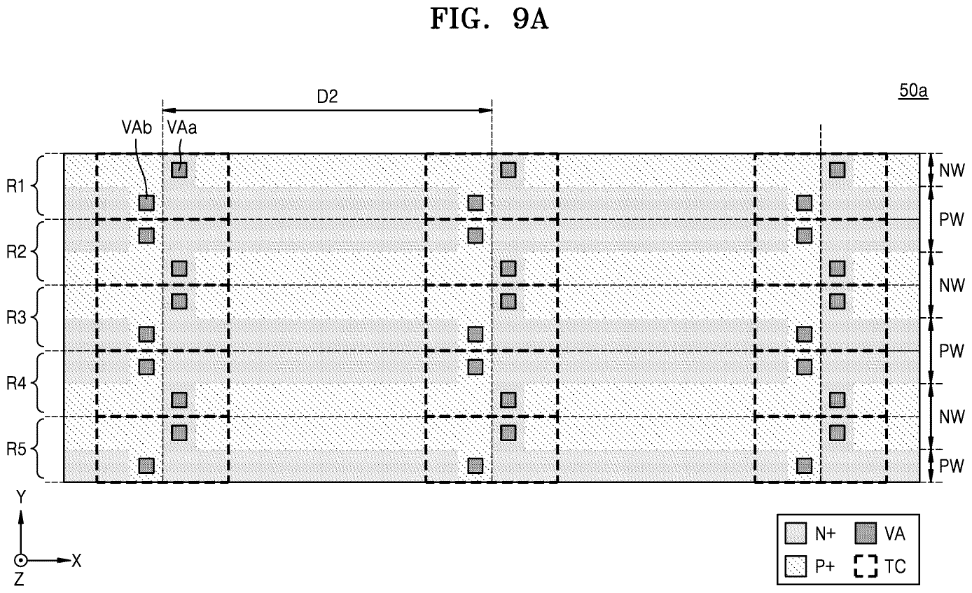

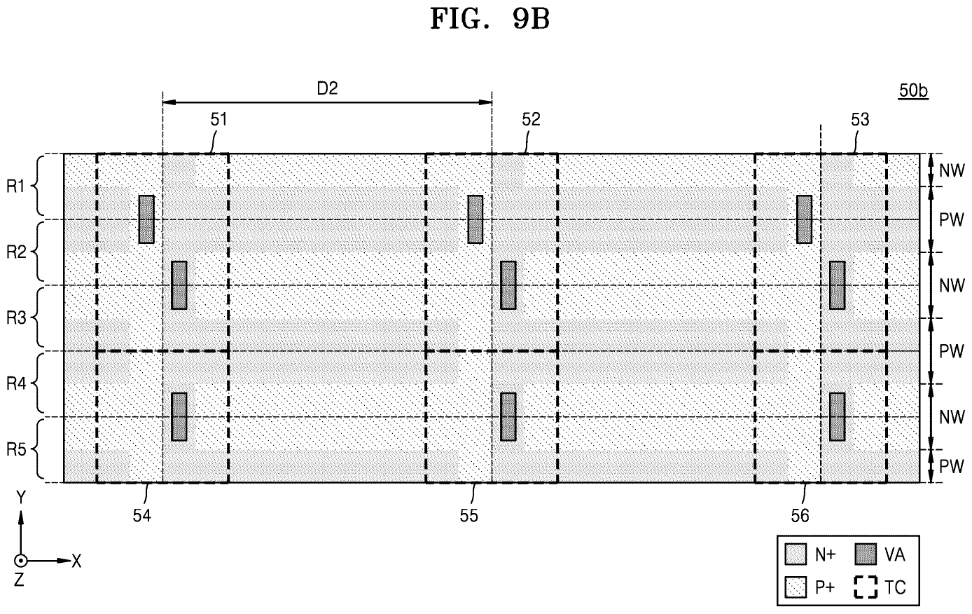

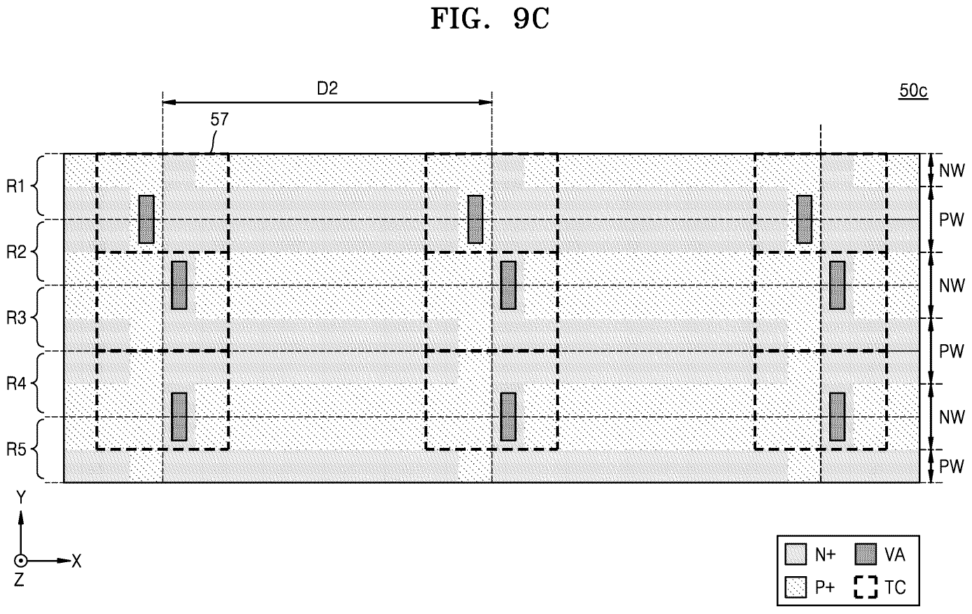

FIG. 9A is a plan view illustrating an example of an integrated circuit 50a.

Referring to FIG. 9A, the integrated circuit 50a may include N wells NW and P wells PW each extending in the first direction X and first and second impurity regions N+ and P+ arranged as jog pattern types or jogging pattern types on the N wells NW and P wells PW. In addition, the integrated circuit 50a may further include the tap cells TC arranged as inline types. For example, three tap cells TC are arranged in each of the first to fifth rows R1 to R5, and a distance between the center lines of two adjacent tap cells TC among the three tap cells TC may correspond to the second distance D2.

For example, each of the tap cells TC may include a merged nanosheet (e.g., mNS of FIGS. 1A to 1E), such as the tap cells 10a to 10e of FIGS. 1A to 1E. In addition, each of the tap cells TC may include vias VA. The power supply voltage VDD may be provided to the first impurity region N+ and the N well NW through the vias VAa and the ground voltage VSS may be provided to the second impurity region P+ and the P well PW through the vias VAb. Function cells may be arranged around the tap cells TC, and each function cell may include a plurality of normal nanosheets (e.g., nNS of FIGS. 1A to 1E).

FIG. 9B is a plan view illustrating an example of an integrated circuit 50b.

Referring to FIG. 5B, the integrated circuit 50b corresponds to a modified example of the integrated circuit 50a of FIG. 9A, and the following description focuses on the differences from FIG. 5A. The integrated circuit 50b may include tap cells 51 to 53 arranged across the first to third rows R1 to R3 and tap cells 54 to 56 arranged across the fourth and fifth rows R4 and R5. The tap cells 51 to 53 may correspond to triple height cells and may include, for example, the tap cell 10c of FIG. 1C. The tap cells 54 to 56 may correspond to double height cells and may include, for example, the tap cell 10b of FIG. 1B. Here, the tap cells 51 to 56 may be arranged as inline types.

FIG. 9C is a plan view illustrating an example of an integrated circuit 50c.

Referring to FIG. 9C, the integrated circuit 50c corresponds to a modified example of the integrated circuit 50a of FIG. 9A, and the following description focuses on the differences from FIG. 9A. The integrated circuit 50c may include tap cells 57 arranged across 1.5 rows. For example, the tap cells 57 may include the tap cells 10d of FIG. 1D and/or the tap cells 10e of FIG. 1E. Here, the tap cells 57 may be arranged as inline types.

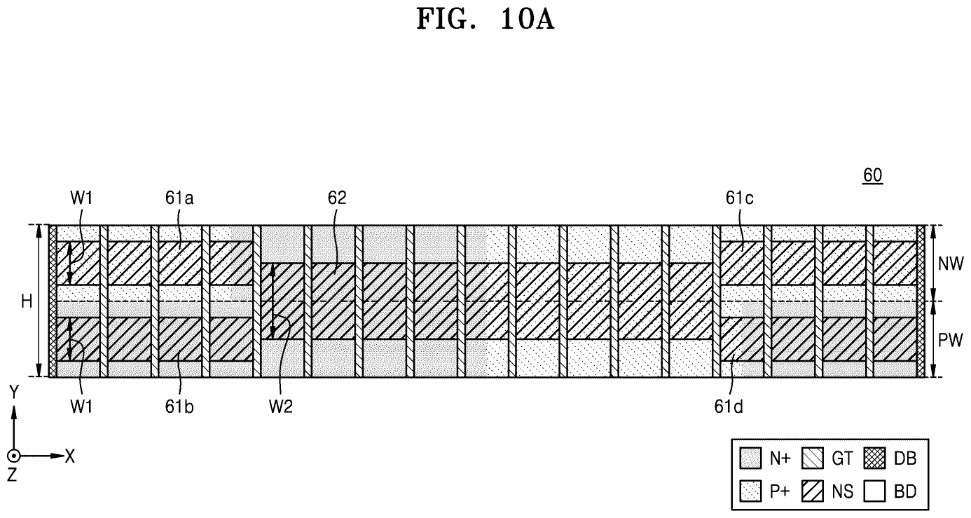

FIGS. 10A and 10B are layout diagrams illustrating an example of a tap cell 60.

Referring to FIG. 10A, the tap cell 60 may correspond to the single height cell having the first cell height H in the second direction Y. The tap cell 60 may include the N well NW and the P well PW each extending in the first direction X, first impurity regions N+ may be arranged in some regions of the N well NW and the P well PW, and second impurity regions P+ may be arranged on other regions of the N well NW and the P well PW. For example, at least one of the first and second impurity regions N+ and P+ may have a jog pattern or a jogging pattern, for example, an L-shaped pattern.

Nanosheets NS may be arranged above the first and second impurity regions N+ and P+. The nanosheets NS may include normal nanosheets 61a to 61d and a merged nanosheet 62. Each of the normal nanosheets 61a to 61d may have the first width W1 in the second direction Y, and the merged nanosheet 62 may have the second width W2 that is greater than the first width W1 in the second direction Y. For example, the second width W2 may correspond to twice the first width W1, but the present disclosure is not limited thereto. In some implementations, the second width W2 may be less than twice the first width W1 or may be greater than twice the first width W1.

In addition, a plurality of gate lines GT extending in the second direction Y and apart from each other in the first direction X may be arranged above the first and second impurity regions N+and P+. The gate lines GT may surround the nanosheets NS, thereby implementing an MBCFET or GAA transistor. For example, the cell boundary BD of the tap cell TC may overlap an isolation structure DB. The isolation structure DB may extend in the second direction Y and may electrically insulate the tap cell 60 from a function cell adjacent in the first direction X. In some implementations, at least one isolation structure DB may be further placed inside the tap cell 60.

Referring to FIG. 10B, the tap cell 60 may further include contacts CA, vias VA, and the first metal layer M1. The contacts CA may correspond to the source/drain contacts arranged on the source/drain and may extend in the second direction Y. The vias VA may be arranged on contacts CA, and the first metal layer M1 may be placed on the vias VA. The first metal layer M1 may include metal patterns M1a and M1b each overlapping the cell boundary BD and extending in the first direction X. The metal pattern M1a may receive the power supply voltage VDD, and the metal pattern M1b may receive the ground voltage VSS.

The vias VA on the first impurity region N+ may constitute an N tap or a first tap 63, and the first tap 63 may provide the power supply voltage VDD received from the metal pattern M1a to the first impurity region N+ and the N well NW through the vias VA and contacts CA. The vias VA on the second impurity region P+ may constitute a substrate tap, a P tap, or a second tap 64, and the second tap 64 may provide the ground voltage VSS received from the metal pattern M1b to the second impurity region P+ and the P well PW through the vias VA and contacts CA.

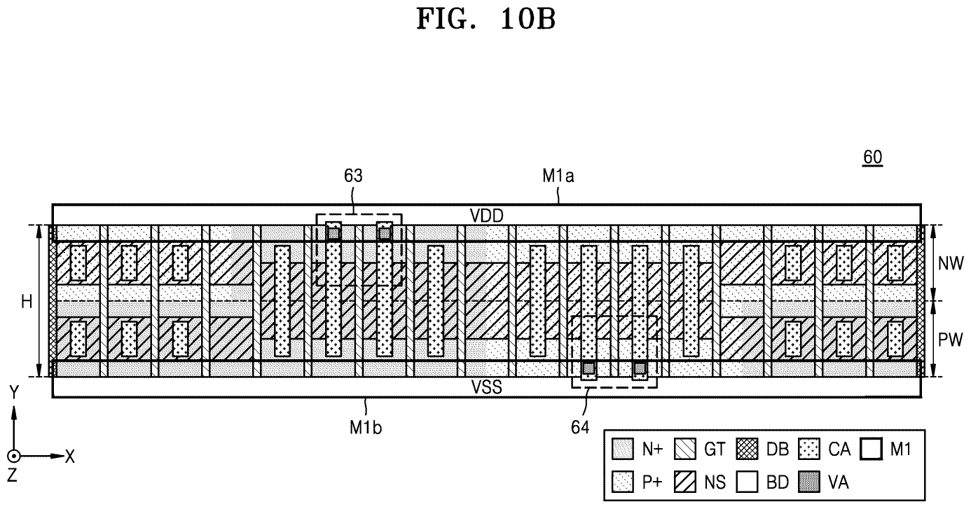

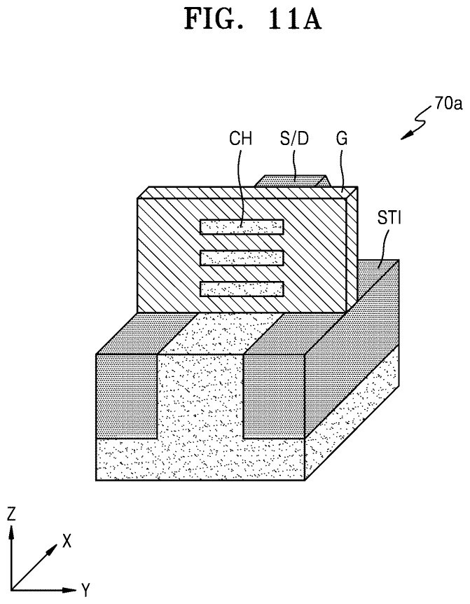

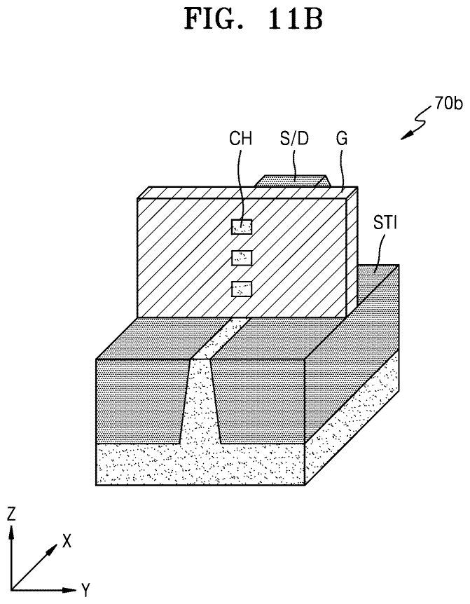

FIGS. 11A and 11B illustrate example devices, respectively. For example, FIG. 11A illustrates an MBCFET 70a including nanosheets. For example, FIG. 11B illustrates a GAAFET 70b including nanowires. For convenience of illustration, FIGS. 11A and 11B illustrate a state in which one of two sources/drains is removed. The tap cells described herein may include GAA transistors, such as the MBCFET 70a of FIG. 11A and the GAAFET 70b of FIG. 11B. However, the present disclosure is not limited thereto, and the merged active pattern or merged nanosheet may be implemented according to various implementations constituting a channel of the GAA transistor.

Referring to FIG. 11A, the MBCFET 70a may be formed by active patterns, i.e., nanosheets, extending in the first direction X and apart from each other in the vertical direction Z and a gate line G extending in the second direction Y. The nanosheets may each extend in the first direction X above the active region defined by device isolation films, such as shallow trench isolation (STI). The nanosheets may have a greater width in the second direction Y compared to nanowires. A source/drain S/D may be formed on opposite sides of the gate line G, and thus the source and drain may be apart from each other in the first direction X. An insulating film, i.e., a gate insulating film, may be formed between the channel CH and the gate line G. However, the number of nanosheets included in the MBCFET 70a is not limited to that shown in FIG. 11A. In addition, the width of each nanosheet included in the MBCFET 70a may vary. For example, the width of a merged nanosheet may be greater than the width of a normal nanosheet.

Referring to FIG. 11B, the GAAFET 70b may be formed by active patterns, e.g., nanowires, extending in the first direction X and apart from each other in the vertical direction Z and a gate line G extending in the second direction Y. The nanowires may each extend in the first direction X from the top of the active region defined by device isolation films, such as STI. A source/drain S/D may be formed on opposite sides of a gate line G, and thus the source and drain S/D may be apart from each other in the first direction X. An insulating film, i.e., a gate insulating film, may be formed between the channel CH and the gate line G. However, the number of nanowires included in GAAFET 70b is not limited to that shown in FIG. 11B. In addition, the width of each nanowire included in the GAAFET 70b may vary.

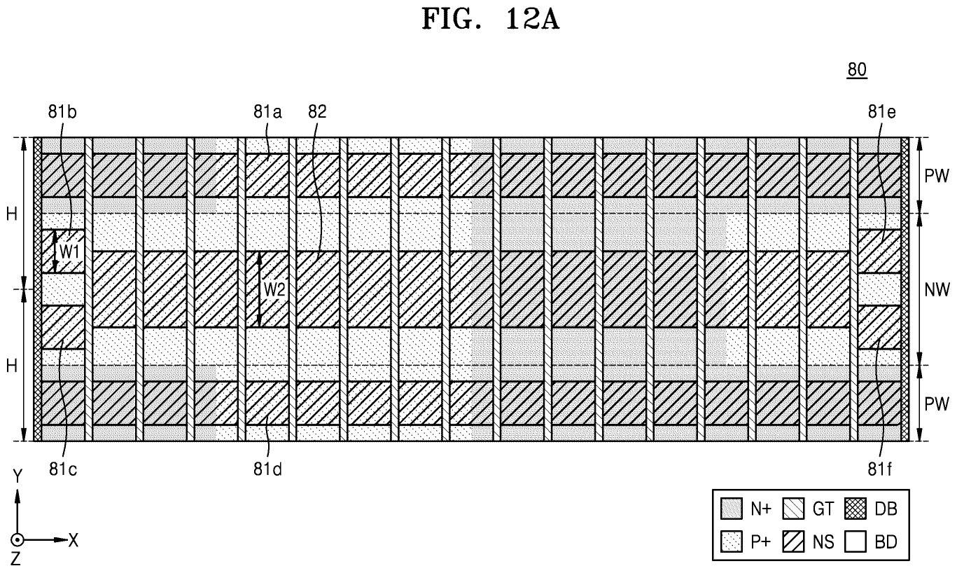

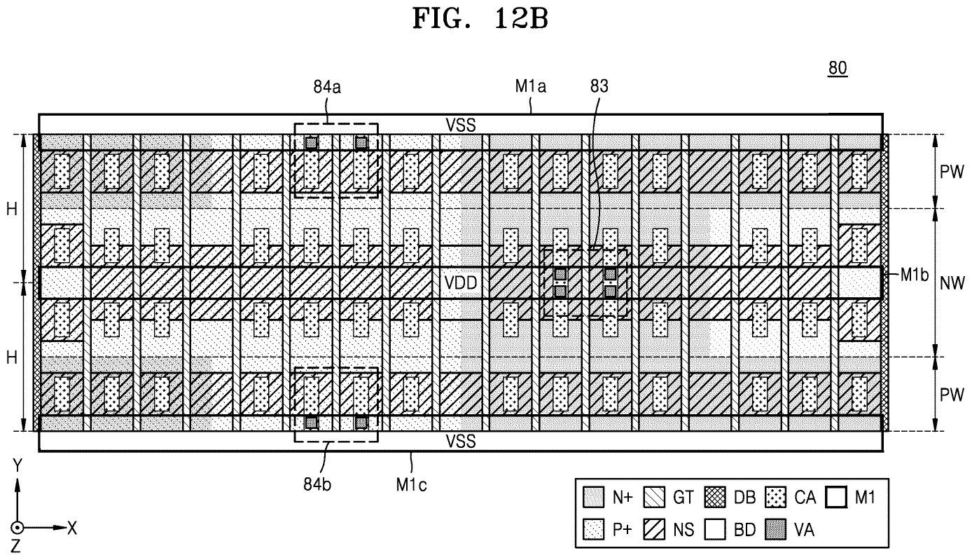

FIGS. 12A and 12B are layout diagrams illustrating an example of a tap cell 80.

Referring to FIG. 12A, the tap cell 80 may correspond to the double height cell having the second cell height (2×H) in the second direction Y. The tap cell 80 may correspond to a modified example of the tap cell 60 illustrated in FIGS. 10A and 10B, and the description given above with reference to FIGS. 10A to 11B may also be applied to the present implementation. The tap cell 80 may include N wells NW and P wells PW each extending in the first direction X, first impurity regions N+ may be arranged in some regions of the N well NW and the P well PW, and second impurity regions P+ may be arranged on other regions of the N well NW and the P well PW.

Nanosheets NS may be arranged above the first and second impurity regions N+ and P+. The nanosheets NS may include normal nanosheets 81a to 81f and a merged nanosheet 82. Each of the normal nanosheets 81a to 81f may have the first width W1 in the second direction Y, and the merged nanosheet 82 may have the second width W2 that is greater than the first width W1 in the second direction Y. In addition, the gate lines GT extending in the second direction Y and apart from each other in the first direction X may be arranged above the first and second impurity regions N+ and P+. The gate lines GT may surround the nanosheets NS.

Referring to FIG. 12B, the tap cell 80 may include contacts CA, vias VA, and the first metal layer M1. The contacts CA may correspond to the source/drain contacts arranged on the source/drain and may extend in the second direction Y. The vias VA may be arranged on contacts CA, and the first metal layer M1 may be placed on the vias VA. The first metal layer M1 may include metal patterns M1a to M1c each extending in the first direction X. The metal patterns M1a and M1c overlap the cell boundary BD and may receive the ground voltage VSS, and the metal pattern M1b may be placed inside the tap cell 80 and may receive the power supply voltage VDD.

The vias VA on the first impurity region N+ may constitute an N tap or a first tap 83, and the first tap 83 may provide the power supply voltage VDD received from the metal pattern M1b to the first impurity region N+ and the N well NW through the vias VA and contacts CA. In some implementations, the first tap 83 may include a plurality of vias VA adjacent to each other in the second direction Y. In some implementations, the first tap 83 may include a long via extending in the second direction Y. In this manner, by increasing the via area of the first tap 83, via resistance may be reduced.

The vias VA on the second impurity region P+ may constitute a substrate tap, a P tap, or second taps 84a and 84b, and the second taps 84a and 84b may provide the ground voltage VSS received from the metal patterns M1a and M1c to the second impurity region P+ and the P well PW through the vias VA and the contacts CA. In some implementations, the contacts CA corresponding to the second taps 84a and 84b may extend further in the second direction Y, and accordingly, each of the second taps 84a and 84b may include a plurality of vias VA adjacent to each other in the second direction Y. In some implementations, the contacts CA corresponding to the second taps 84a and 84b may further extend in the second direction Y, and accordingly, each of the second taps 84a and 84b may include a long via extending in the second direction Y. In this manner, by increasing the via area of the second taps 84a and 84b, via resistance may be reduced. some implementations, the size of the first tap 83 may be different from the size of each of the second taps 84a and 84b. In some implementations, the number and/or size of the vias of the first tap 83 may be different from the number and/or size of the vias of each of the second taps 84a and 84b.

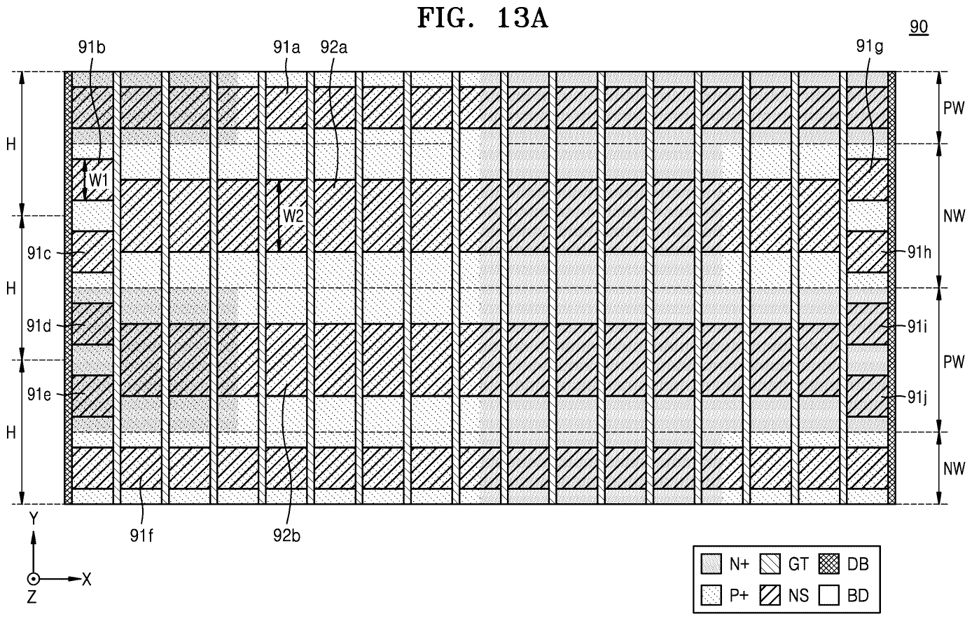

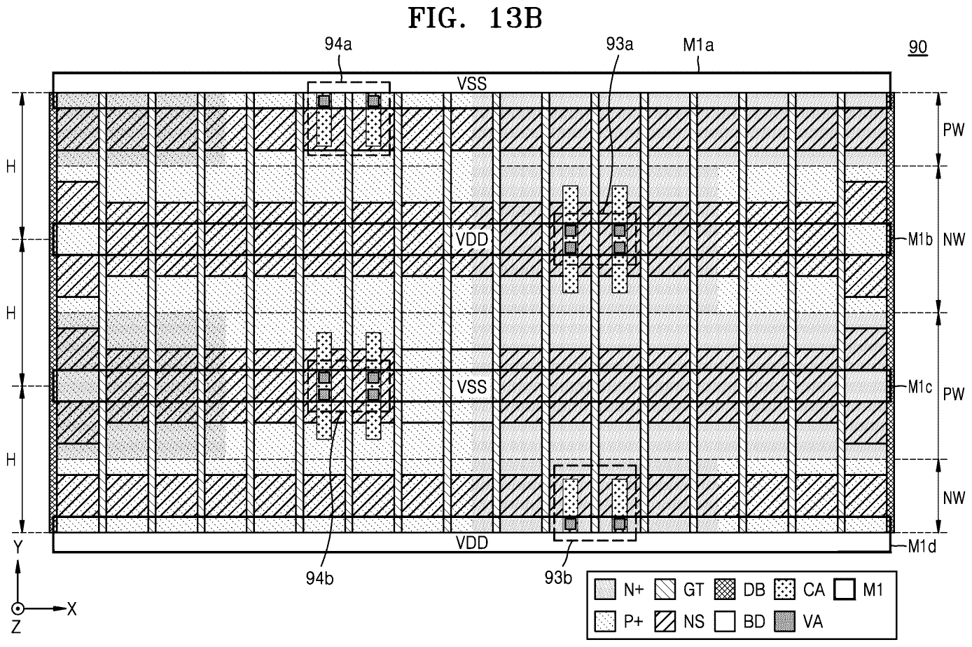

FIGS. 13A and 13B are layout diagrams illustrating an example of a tap cell 90.

Referring to FIG. 13A, the tap cell 90 may correspond to the triple height cell having the third cell height (3×H) in the second direction Y. The tap cell 90 corresponds to a modified example of the tap cell 60 illustrated in FIGS. 10A and 10B, and the description given above with reference to FIGS. 10A to 11B may also be applied to the present implementation. The tap cell 90 may include N wells NW and P wells PW each extending in the first direction X, first impurity regions N+ may be arranged in some regions of the N wells NW and the P wells PW, and second impurity regions P+ may be arranged on other regions of the N wells NW and the P wells PW.

Nanosheets NS may be arranged above the first and second impurity regions N+ and P+. The nanosheets NS may include normal nanosheets 91a to 91j and merged nanosheets 92a and 92b. Each of the normal nanosheets 91a to 91j may have the first width W1 in the second direction Y, and each of the merged nanosheets 92a and 92b may have the second width W2 that is greater than the first width W1 in the second direction Y. In addition, the gate lines GT extending in the second direction Y and apart from each other in the first direction X may be arranged above the first and second impurity regions N+ and P+. The gate lines GT may surround the nanosheets NS.

Referring to FIG. 13B, the tap cell 90 may include contacts CA, vias VA, and the first metal layer M1. The contacts CA may correspond to the source/drain contacts arranged on the source/drain and may extend in the second direction Y. The vias VA may be arranged on contacts CA, and the first metal layer M1 may be placed on the vias VA. The first metal layer M1 may include metal patterns M1a to M1d each extending in the first direction X. Metal patterns M1a and M1d may overlap the cell boundary BD, and metal patterns M1b and M1c may be arranged inside the tap cell 90. The metal patterns M1a and M1c may receive the ground voltage VSS, and the metal patterns M1b and M1d may receive the power supply voltage VDD.

The vias VA on the first impurity region N+ may constitute N taps or first taps 93a and 93b, and the first taps 93a and 93b may provide the power supply voltage VDD received from the metal patterns M1b and M1d to the first impurity region N+ and the N well NW through the vias VA and the contacts CA. In some implementations, the first tap 93a may include a plurality of vias VA adjacent to each other in the second direction Y. In some implementations, the first tap 93a may include a long via extending in the second direction Y. In some implementations, the contacts CA corresponding to the first tap 93b may extend further in the second direction Y, such that the first tap 93b may include a plurality of vias VA adjacent to each other in the second direction Y. In some implementations, the contacts CA corresponding to the first tap 93b may extend further in the second direction Y, such that the first tap 93b may include a long via extending in the second direction Y. In this manner, by increasing the via area of the first taps 93a and 93b, resistance may be reduced.

The vias VA on the second impurity region P+ may constitute substrate taps, P taps, or second taps 94a and 94b, and the second taps 94a and 94b may provide the ground voltage VSS received from the metal patterns M1a and M1c to the second impurity region P+ and the P well PW through the vias VA and the contacts CA. In some implementations, the second tap 94b may include a plurality of vias VA adjacent to each other in the second direction Y. In some implementations, the second tap 94b may include a long via extending in the second direction Y. In some implementations, the contacts CA corresponding to the second tap 94a may extend further in the second direction Y such that the second tap 94a may include a plurality of vias VA adjacent to each other in the second direction Y. In some implementations, the contacts CA corresponding to the second tap 94a may extend further in the second direction Y such that the second tap 94a may include a long via extending in the second direction Y. In this manner, by increasing the via area of the first taps 93a and 93b, the resistance may be reduced. In some implementations, the size of the first taps 93a and 93b may be different from the size of each of the second taps 94a and 94b. In some implementations, the number and/or size of vias of the first taps 93a and 93b may be different from the number and/or size of vias of each of the second taps 94a and 94b.

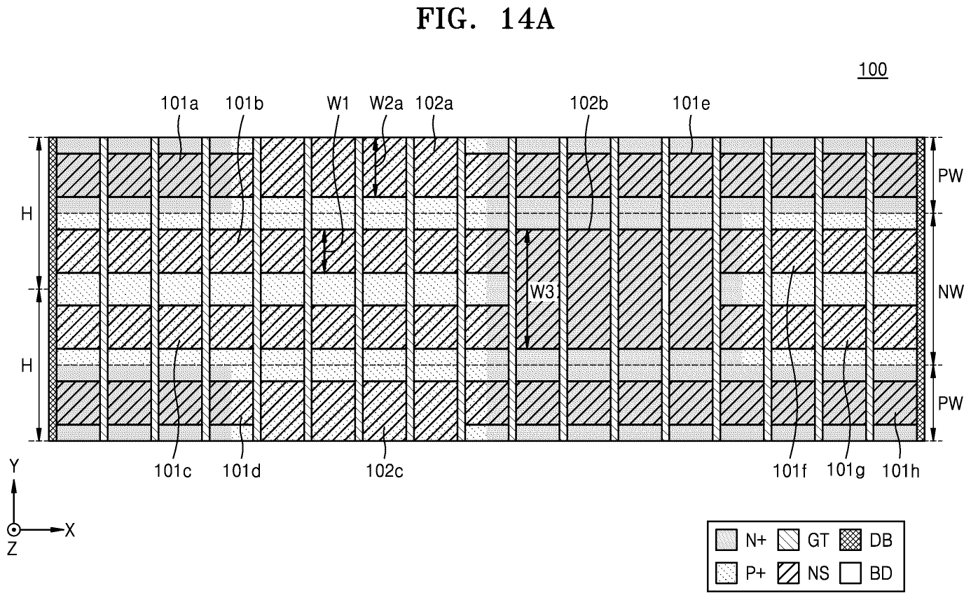

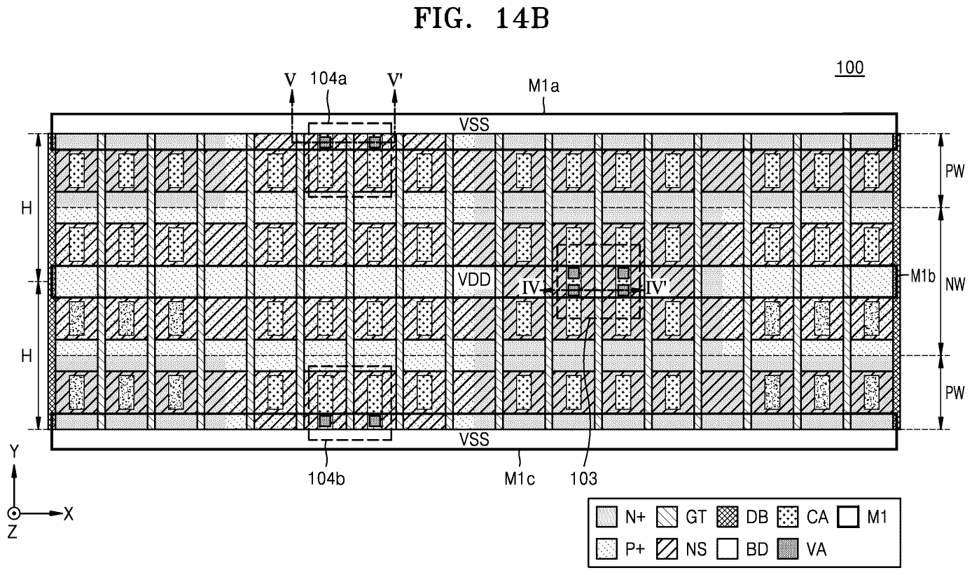

FIGS. 14A and 14B are layout diagrams illustrating an example of a tap cell 100.

Referring to FIG. 14A, the tap cell 100 may correspond to the double height cell having the second cell height (2×H) in the second direction Y. The tap cell 100 may correspond to a modified example of the tap cell 80 illustrated in FIGS. 12A and 12B, and the description given above with reference to FIGS. 12A and 12B may also be applied to the present implementation. The nanosheets NS may include normal nanosheets 101a to 101h, wide nanosheets 102a and 102c, and a merged nanosheet 102b. The wide nanosheets 102a and 102c may be arranged above the P wells PW, respectively, and the merged nanosheet 102b may be arranged above the N well NW. However, the present disclosure is not limited thereto, and normal nanosheets may be respectively arranged above the P wells PW, and merged nanosheets may be arranged only above the N wells NW.

Each of the normal nanosheets 101a to 101h may have the first width W1 in the second direction Y, each of the wide nanosheets 102a and 102c may have a second width W2a that is greater than the first width W1 in the second direction Y, and the merged nanosheet 102b may have a third width W3 that is greater than the second width W2a in the second direction Y. For example, the third width W3 may be greater than twice the first width W1. For example, the third width W3 may correspond to the sum of twice the first width W1 and a space between the normal nanosheets 101b and 101c, and thus, the normal nanosheets 101b, 101c, 101f, and 101g and the merged nanosheet 102b may be implemented in an I-shape. For example, the normal nanosheets 101a and 101e and the wide nanosheet 102a may be implemented in an inverted T shape. For example, the normal nanosheets 101d and 101h and the wide nanosheets 102c may have a T shape.

Referring to FIG. 14B, the tap cell 100 may further include contacts CA, vias VA, and the first metal layer M1. The first metal layer M1 may include metal patterns M1a to M1c each extending in the first direction X. The metal patterns M1a and M1c may overlap the cell boundary BD and may receive the ground voltage VSS, and the metal pattern M1b may be placed inside the tap cell 100 and may receive the power supply voltage VDD.

The vias VA on the first impurity region N+ may constitute an N tap or a first tap 103, and the first tap 103 may provide the power supply voltage VDD received from the metal pattern M1b to the first impurity region N+ and the N well NW through the vias VA and contacts CA. In some implementations, the first tap 103 may include a plurality of vias VA arranged in the second direction Y. In some implementations, the first tap 103 may include a long via extending in the second direction Y. In this manner, by increasing the via area of the first tap 103, the via resistance may be reduced. In addition, because the first tap 103 is placed above the merged nanosheet 102b, the size of the contact CA may be increased and an overlapping region between the contact CA and the active pattern, i.e., the merged nanosheet 102b, may be increased, thereby further reducing the resistance of the first tap 103.

The vias VA on the second impurity region P+ may constitute substrate taps, P taps, or second taps 104a and 104b, and the second taps 104a and 104b may provide the ground voltage VSS received from the metal patterns M1a and M1c to the second impurity region P+ and the P well PW through the vias VA and the contacts CA. In some implementations, the contacts CA corresponding to the second taps 104a and 104b may extend further in the second direction Y such that the second taps 104a and 104b may include the vias VA arranged in the second direction Y, respectively. In some implementations, the contacts CA corresponding to the second taps 104a and 104b may further extend in the second direction Y such that each of the second taps 104a and 104b may include a long via extending in the second direction Y. In this manner, by increasing the via area of the second taps 104a and 104b, the via resistance may be reduced. Here, the size of the first tap 103 may be different from the size of each of the second taps 104a and 104b. In addition, the number and/or size of the vias of the first tap 103 may be different from the number and/or size of the vias of each of the second taps 104a and 104b.

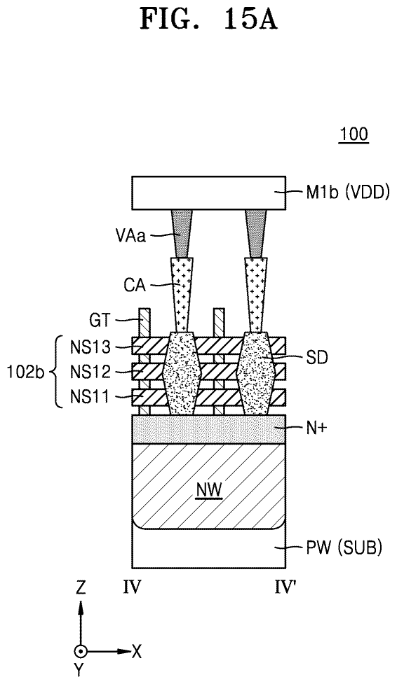

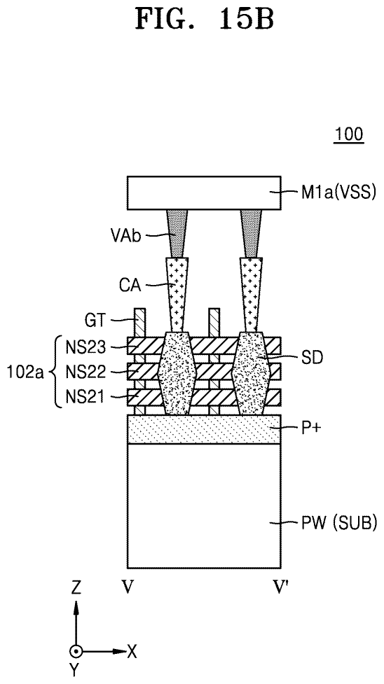

FIG. 15A is an example of a cross-sectional view taken along line IV-IV′ of FIG. 14B, and FIG. 15B is an example of a cross-sectional view taken along line V-V′ of FIG. 14B.

Referring to FIG. 15A, the first tap 103 included in the tap cell 100 may include a plurality of vias VAa. The vias VAa may receive the power supply voltage VDD from the metal pattern M1b placed above the front side FS of the substrate SUB. Each via VAa may provide the power supply voltage VDD to the first impurity region N+ and N well NW through the contact CA and the source/drain SD. However, the present disclosure is not limited thereto, and the tap cell 100 may not include the source/drain SD. Here, each via VAa may provide the power supply voltage VDD to the first impurity region N+ and N well NW through the contact CA. For example, each via VAa may penetrate the merged nanosheet 102b and be insulated from the merged nanosheet 102b.

The merged nanosheet 102b may include a plurality of nanosheets NS11 to NS13 apart from each other in the vertical direction Z and may be referred to as a first nanosheet stack. The gate line GT may surround each of nanosheets NS11 to NS13 while covering the first nanosheet stack or merged nanosheet 102b. The plurality of nanosheets NS11 to NS13 may have a GAA structure surrounded by the gate line GT. A gate insulating film may be located between the nanosheets NS11 to NS13 and the gate line GT. In addition, a gate insulating film may be formed between the gate line GT and the substrate SUB. The gate line GT may be defined as a conductive segment including a conductive material, such as polysilicon and one or more metals.

Referring to FIG. 15B, the second tap 104a included in the tap cell 100 may include a plurality of vias VAb. The vias VAb may receive the ground voltage VSS from the metal pattern M1a placed above the front side FS of the substrate SUB. Each via VAb may provide the ground voltage VSS to the second impurity region P+ and P well PW through the contact CA and source/drain SD. However, the present disclosure is not limited thereto, and the tap cell 100 may not include the source/drain SD. Here, each via VAb may provide the ground voltage VSS to the second impurity region P+ and P well PW through the contact CA. For example, each via VAb may penetrate the wide nanosheet 102a and be insulated from the wide nanosheet 102a.

The wide nanosheet 102a may include the nanosheets NS21 to NS23 apart from each other in the vertical direction Z and may be referred to as a second nanosheet stack. The gate line GT may surround each of the nanosheets NS21 to NS23 while covering the second nanosheet stack or wide nanosheet 102a. The nanosheets NS21 to NS23 may have a GAA structure surrounded by the gate line GT. A gate insulating film may be between the nanosheets NS21 to NS23 and the gate line GT.

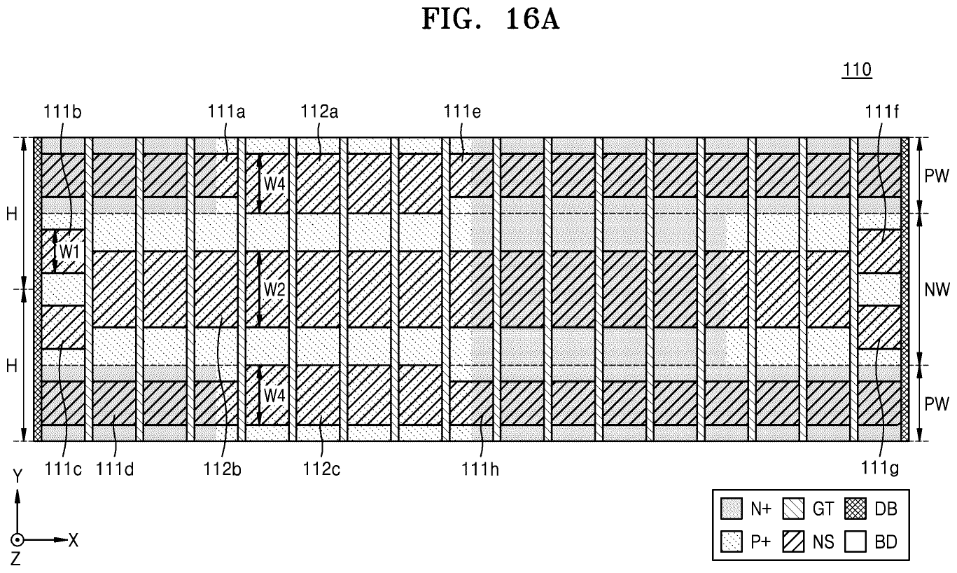

FIGS. 16A and 16B are layout diagrams illustrating an example of a tap cell 110.

Referring to FIG. 16A, the tap cell 110 may correspond to the double height cell having the second cell height (2×H) in the second direction Y. The tap cell 110 may correspond to a modified example of the tap cell 100 illustrated in FIGS. 14A and 14B, and the description given above with reference to FIGS. 14A to 15B may also be applied to the present implementation. The nanosheets NS may include normal nanosheets 111a to 111h, wide nanosheets 112a and 112c, and a merged nanosheet 112b. The wide nanosheets 112a and 112c may be arranged above the P wells PW, respectively, and the merged nanosheet 112b may be placed above the N well NW.

Each of the normal nanosheets 111a to 111h may have the first width W1 in the second direction Y, the merged nanosheet 112b may have the second width W2 that is greater than the first width W1 in the second direction Y, and each of the wide nanosheets 112a and 112c may have a fourth width W4 that is greater than the first width W1 in the second direction Y. For example, the second width W2 may be greater than the fourth width W4, but the present disclosure is not limited thereto. For example, the normal nanosheets 111a and 111e and the wide nanosheet 112a may have a T shape. For example, the normal nanosheets 111d and 111h and the wide nanosheet 112c may be implemented in an inverted T shape.

Referring to FIG. 16B, the tap cell 110 may further include contacts CA, vias VA, and the first metal layer M1. The vias VA on the first impurity region N+ may constitute an N tap or a first tap 113, and the first tap 113 may provide the power supply voltage VDD received from the metal pattern M1b to the first impurity region N+ and the N well NW through the vias VA and contacts CA. In some implementations, the first tap 103 may include a plurality of vias VA adjacent to each other in the second direction Y. In some implementations, the first tap 103 may include a long via extending in the second direction Y. In this manner, by increasing the via area of the first tap 103, the via resistance may be reduced.

The vias VA on the second impurity region P+ may constitute substrate taps, P taps, or second taps 114a and 114b, and the second taps 114a and 114b may provide the ground voltage VSS received from the metal patterns M1a and M1c to the second impurity region P+ and the P well PW through the vias VA and the contacts CA. Here, because the second taps 114a and 114b are respectively placed above the wide nanosheets 112a and 112c, the size of the contact CA may be increased and an overlapping region between the contact CA and the active pattern, i.e., the wide nanosheets 112a and 112c, may be increased, thereby further reducing the resistance of the second taps 114a and 114b.

In some implementations, the contacts CA corresponding to the second taps 114a and 114b may extend further in the second direction Y such that each of the second taps 114a and 114b may include a plurality of vias VA adjacent to each other in the second direction Y. In some implementations, the contacts CA corresponding to the second taps 114a and 114b may further extend in the second direction Y such that each of the second taps 114a and 114b may include a long via extending in the second direction Y. In this manner, by increasing the via area of the second taps 114a and 114b, the via resistance may be reduced.

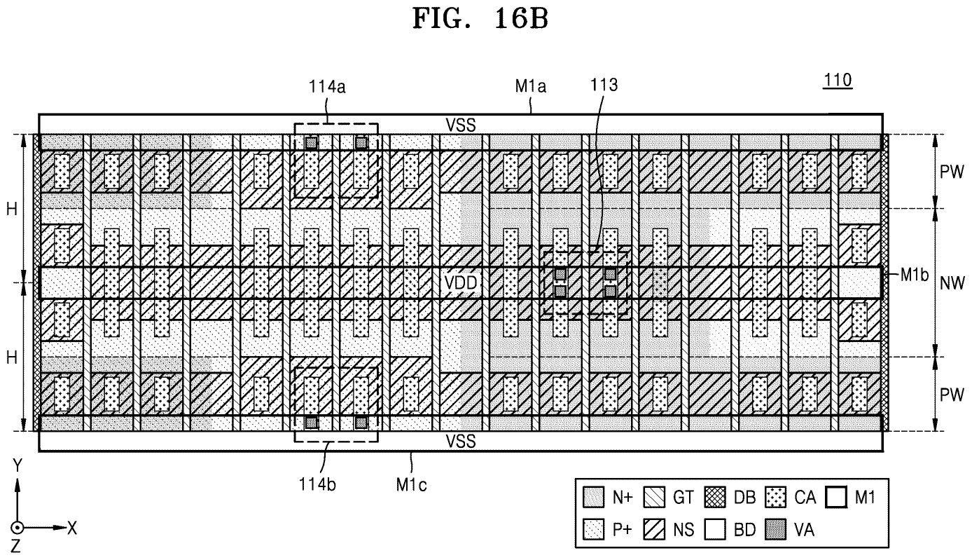

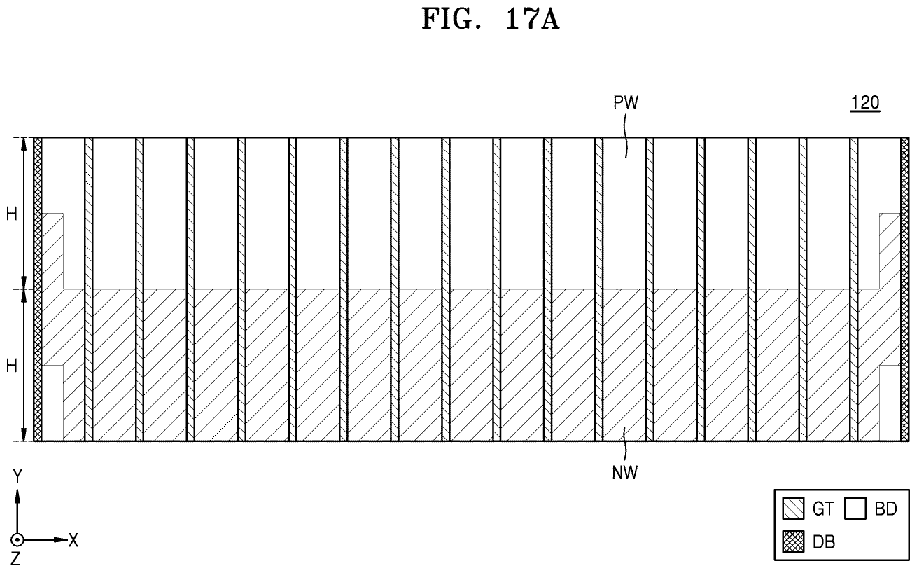

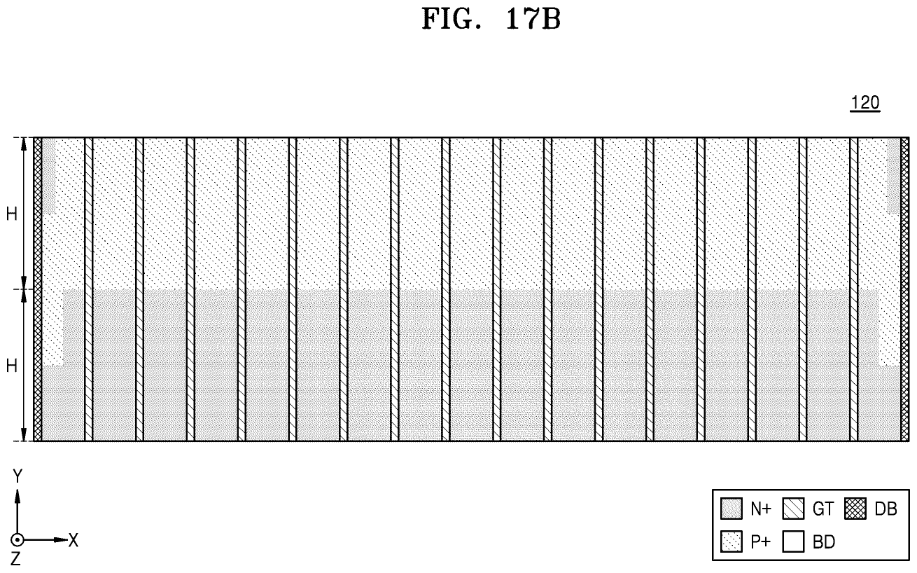

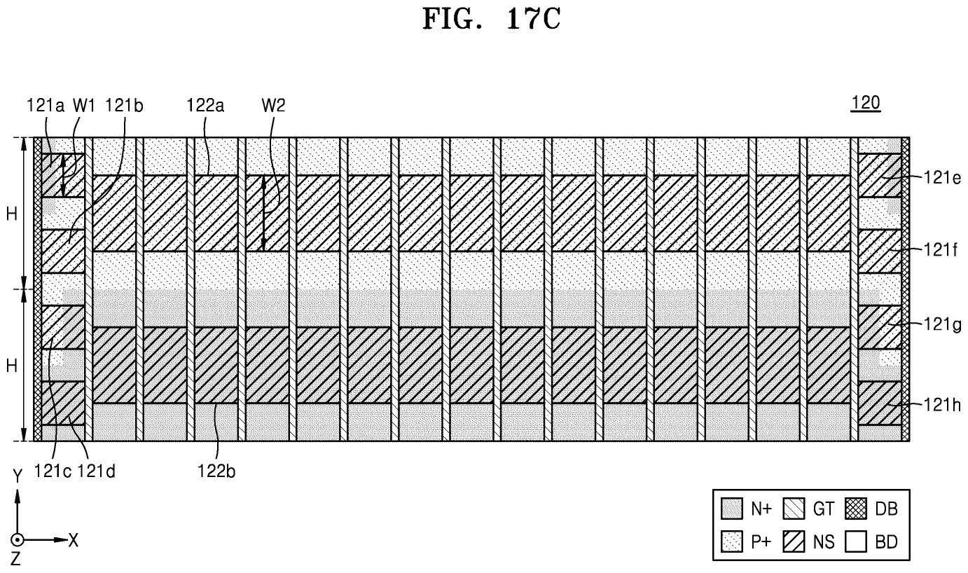

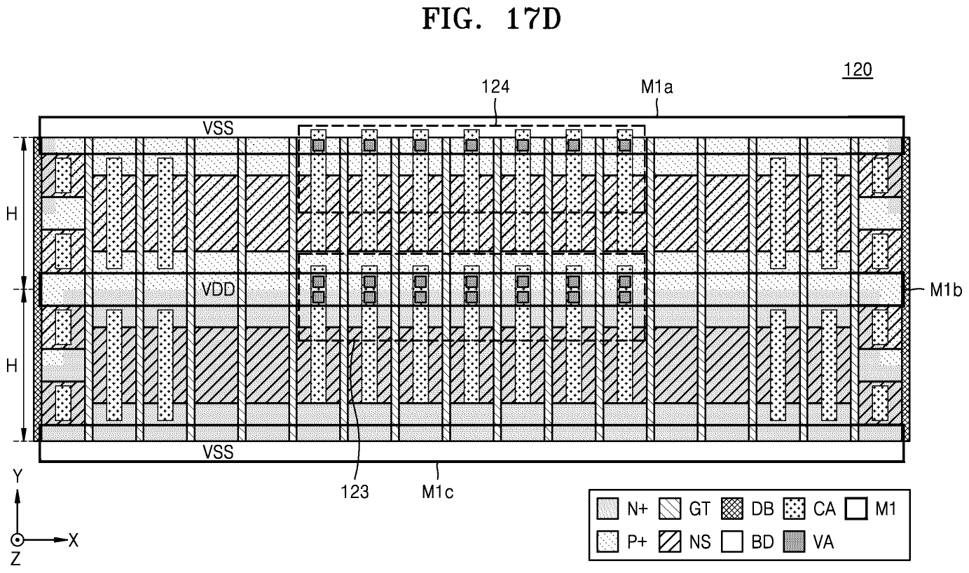

FIGS. 17A to 17D are layout diagrams illustrating an example of a tap cell 120.

Referring to FIGS. 17A and 17B, the tap cell 120 may correspond to the double height cell having the second cell height (2×H) in the second direction Y. The tap cell 120 may correspond to a modified example of the tap cell 80 illustrated in FIGS. 12A and 12B, and the description given above with reference to FIGS. 12A and 12B may also be applied to the present implementation. The tap cell 120 may include the N well NW and the P well PW, and each of the N well NW and the P well PW may have a jog pattern or jogging pattern. The tap cell 120 may further include first and second impurity regions N+ and P+. The first impurity regions N+ may be arranged in some regions of the N well NW and the P well PW, and the second impurity regions P+ may be arranged in other some regions of the N well NW and the P well PW.

Referring to FIG. 17C, the nanosheets NS may be arranged above the first and second impurity regions N+ and P+. The nanosheets NS may include normal nanosheets 121a to 121h and merged nanosheets 122a and 122b. The merged nanosheet 122a may be arranged above the P well PW and the second impurity region P+, and the merged nanosheet 122b may be placed above the N well NW and the first impurity region N+. Each of the normal nanosheets 121a to 121h may have the first width W1 in the second direction Y, and each of the merged nanosheets 122a and 122b may have the second width W2 that is greater than the first width W1 in the second direction Y.

Referring to FIG. 17D, the tap cell 120 may further include contacts CA, vias VA, and the first metal layer M1. The N tap or first tap 123 may include vias VA below the metal pattern M1b, and the vias VA may provide the power supply voltage VDD received from the metal pattern M1b to the first impurity region N+ and the N well NW through the vias VA and contacts CA. In some implementations, the first tap 123 may include a plurality of vias VA adjacent to each other in the second direction Y. In some implementations, the first tap 123 may include a long via extending in the second direction Y. In this manner, by increasing the via area of the first tap 123, the via resistance may be reduced.

The substrate tap, P tap, or second tap 124 may include vias VA below the metal pattern M1a, and the vias VA may provide the ground voltage VSS received from the metal pattern M1a to the second impurity region P+ and the P well PW through the vias VA and the contacts CA. In some implementations, the contacts CA corresponding to the second tap 124 may extend further in the second direction Y such that the second tap 124 may include a plurality of vias VA adjacent to each other in the second direction Y. In some implementations, the contacts CA corresponding to the second tap 124 may extend further in the second direction Y such that the second tap 124 may include a long via extending in the second direction Y. In this manner, by increasing the via area of the second tap 124, the via resistance may be reduced.

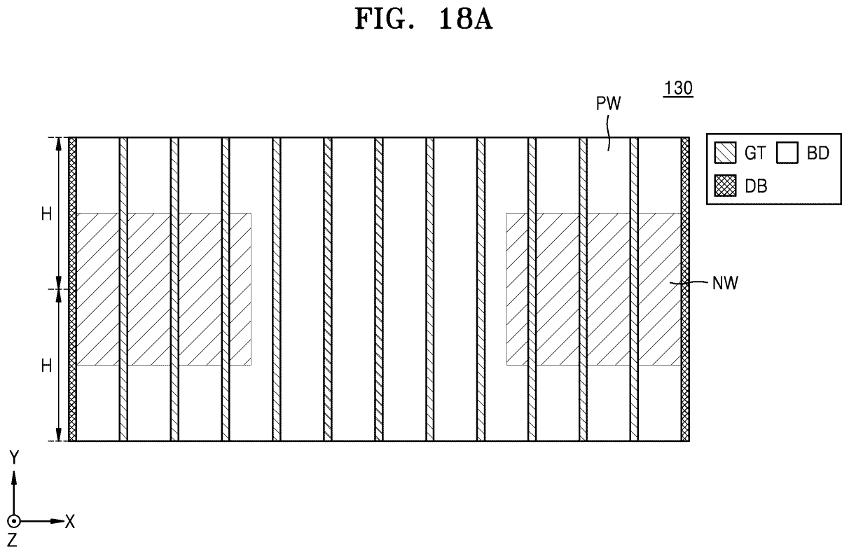

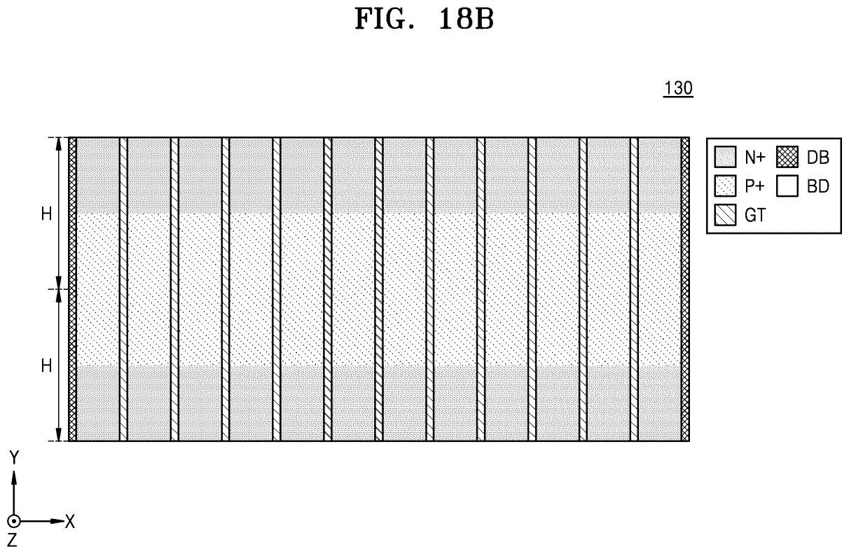

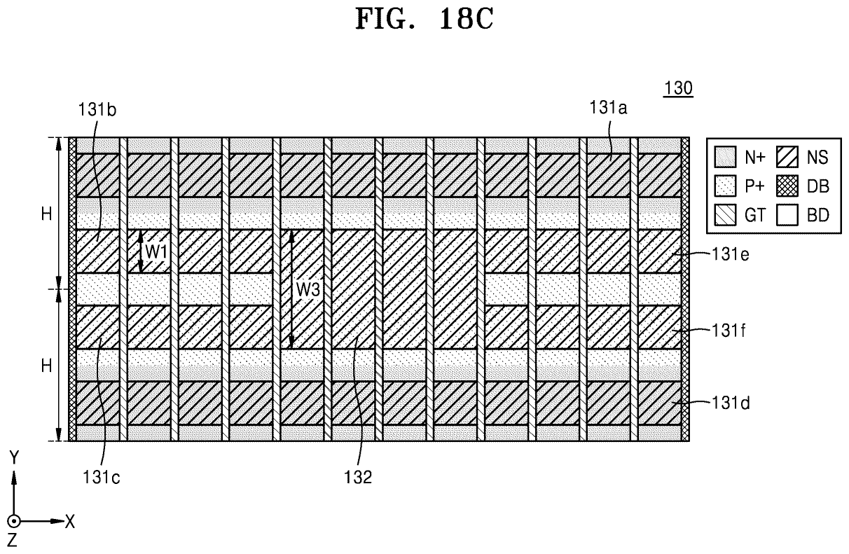

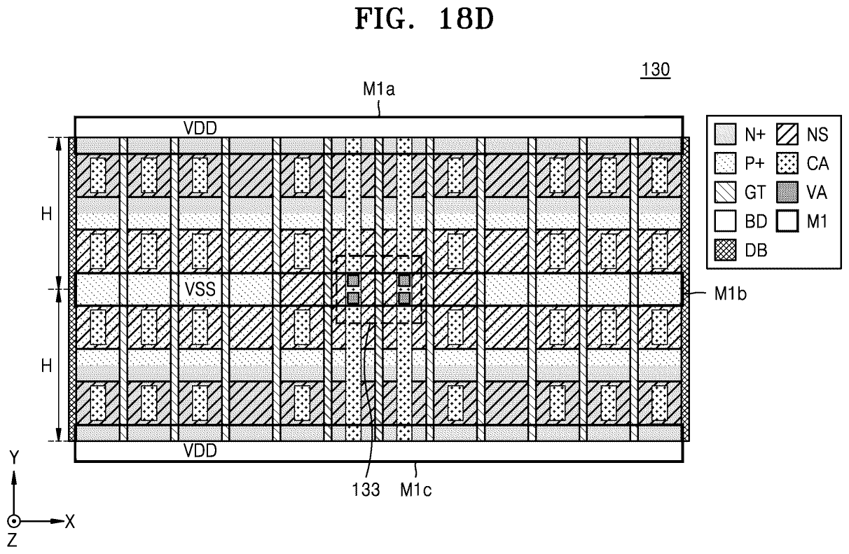

FIGS. 18A, 18B, 18C, and 18D are layout diagrams illustrating an example of a tap cell 130.

Referring to FIGS. 18A and 18B, the tap cell 130 may include N wells NW apart from each other in the first direction X and P wells PW arranged in an I shape between the N wells NW. Here, the P well PW may function as an N well break. The tap cell 130 may further include first and second impurity regions N+ and P+. The first impurity regions N+ may be arranged in some regions of the N well NW and the P well PW, and the second impurity regions P+ may be arranged in other some regions of the N well NW and the P well PW. For example, the first and second impurity regions N+ and P+ may each extend in the first direction X, and the second impurity region P+ may be placed between the first impurity regions N+.

Referring to FIG. 18C, nanosheets NS may be arranged above the first and second impurity regions N+ and P+. The nanosheets NS may include normal nanosheets 131a to 131f and a merged nanosheet 132. The merged nanosheet 132 may be placed above the P well PW and the second impurity region P+. Each of the normal nanosheets 131a to 131f may have the first width W1 in the second direction Y, and the merged nanosheet 132 may have the third width W3 that is greater than the first width W1 in the second direction Y. For example, the third width W3 may correspond to the sum of twice the first width W1 and a space between the normal nanosheets 131b and 131c, and thus, the normal nanosheets 131b, 131c, 131e, and 131f and the merged nanosheet 132 may be implemented in an I-shape.

Referring to FIG. 18D, the tap cell 130 may further include contacts CA, vias VA, and the first metal layer M1. The substrate tap, P tap, or second tap 133 may include vias VA below the metal pattern M1b, and the vias VA may provide the ground voltage VSS received from the metal pattern M1b to the second impurity region P+ and the P well PW through the vias VA and the contacts CA. In some implementations, the second tap 133 may include a plurality of vias VA adjacent to each other in the second direction Y. In some implementations, the second tap 133 may include a long via extending in the second direction Y. In this manner, by increasing the via area of the second tap 133, the via resistance may be reduced.

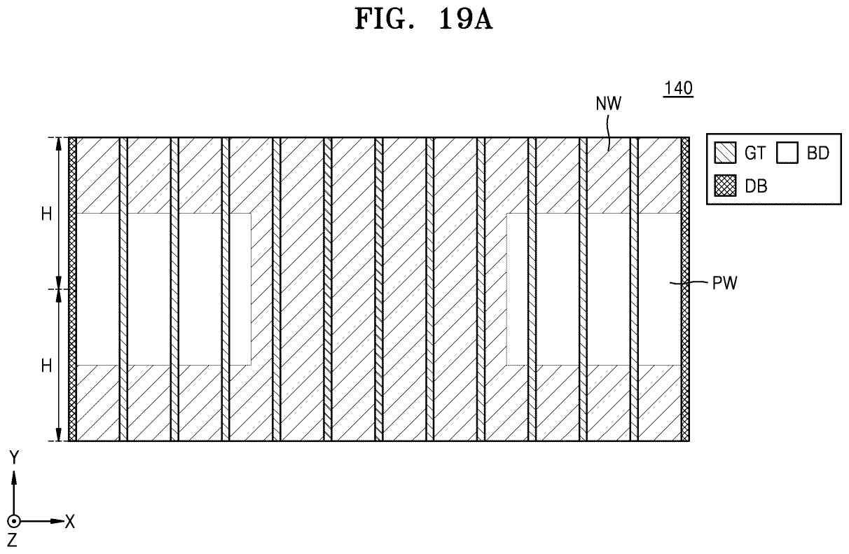

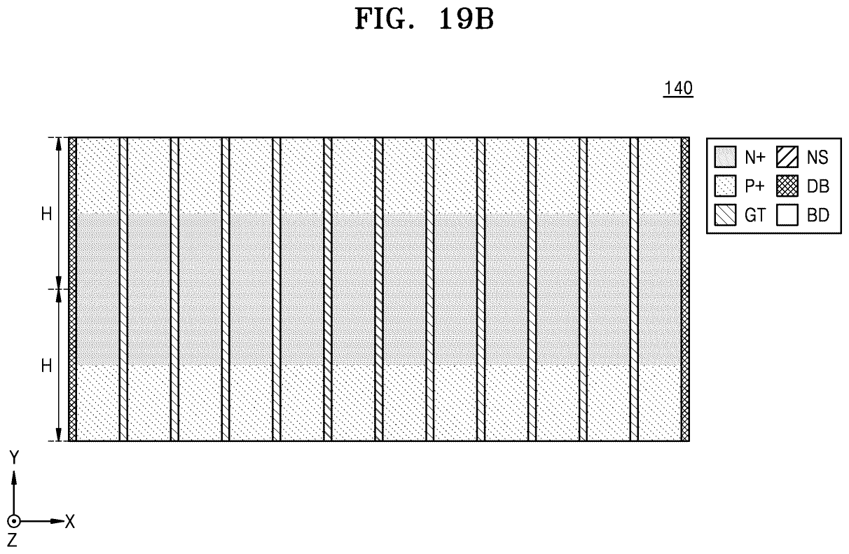

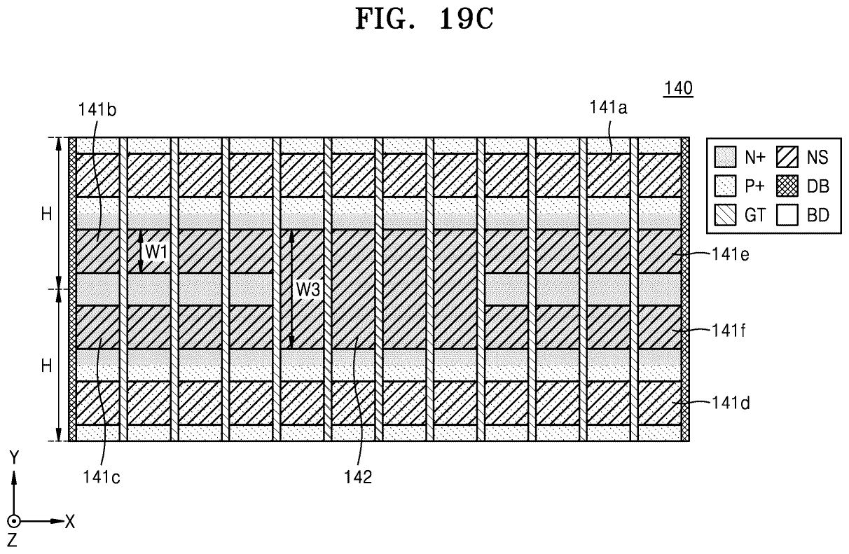

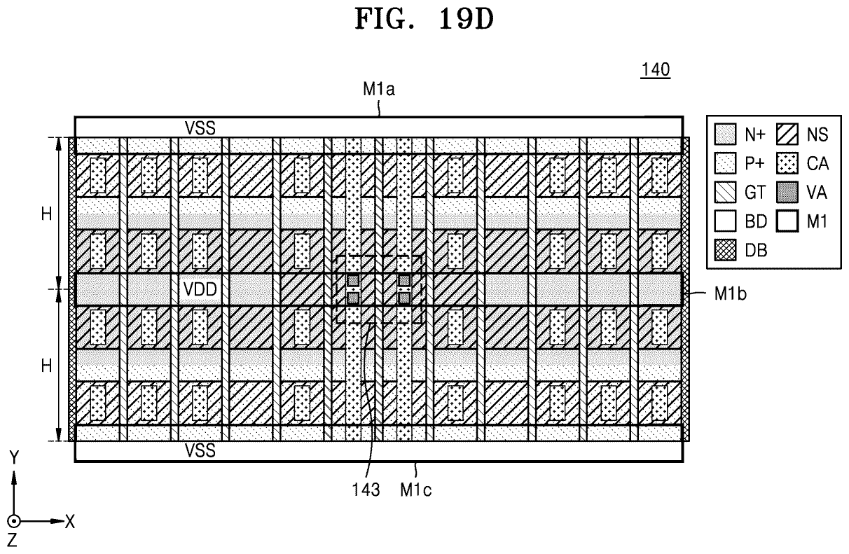

FIGS. 19A, 19B, 19C, and 19D are layout diagrams illustrating an example of a tap cell 140.

Referring to FIGS. 19A and 19B, the tap cell 140 may include P wells PW apart from each other in the first direction X and N wells NW arranged in an I shape between the P wells PW. Here, the N well NW may function as a P well break or a substrate break. The tap cell 140 may further include first and second impurity regions N+ and P+. The first impurity region N+ may be placed in some regions of the N well NW and the P well PW, and the second impurity regions P+ may be placed in other some regions of the N well NW and the P well PW. For example, the first and second impurity regions N+ and P+ may each extend in the first direction X, and the first impurity region N+ may be placed between the second impurity regions P+.

Referring to FIG. 19C, nanosheets NS may be arranged above the first and second impurity regions N+ and P+. The nanosheets NS may include normal nanosheets 141a to 141f and a merged nanosheet 142. The merged nanosheet 142 may be placed above the N well NW and the first impurity region N+. Each of the normal nanosheets 141a to 141f may have the first width W1 in the second direction Y, and the merged nanosheet 142 may have the third width W3 that is greater than the first width W1 in the second direction Y. For example, the normal nanosheets 141b, 141c, 141e, and 141f and the merged nanosheet 142 may be implemented in an I-shape.

Referring to FIG. 19D, the tap cell 140 may further include contacts CA, vias VA, and the first metal layer M1. The N tap or first tap 143 may include vias VA under the metal pattern M1b, and the vias VA may provide the power supply voltage VDD received from the metal pattern M1b to the first impurity region N+ and the N well NW through the vias VA and contacts CA. In some implementations, the first tap 143 may include a plurality of vias VA adjacent to each other in the second direction Y. In some implementations, the first tap 143 may include a long via extending in the second direction Y. In this manner, by increasing the via area of the first tap 143, the via resistance may be reduced.

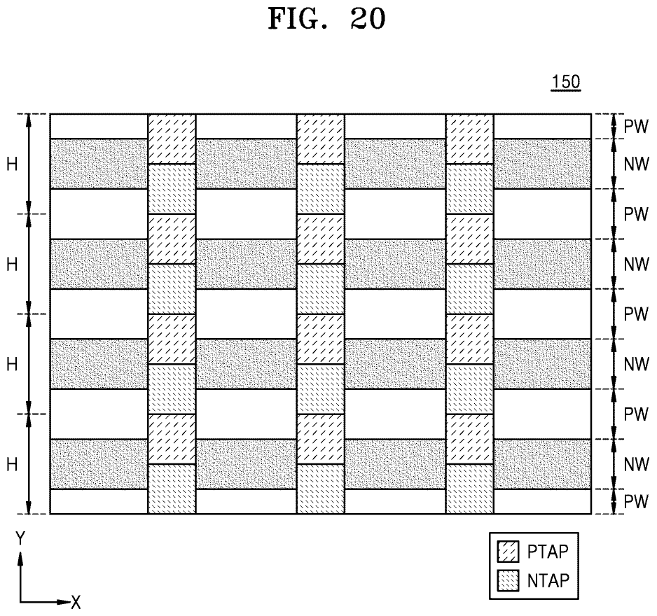

FIG. 20 is a layout diagram illustrating an example of an integrated circuit 150.

Referring to FIG. 20, the integrated circuit 150 may include N wells NW and P wells PW each extending in the first direction X, a plurality of well taps or N taps NTAP, and a plurality of substrate taps or P-taps PTAP. For example, the N taps NTAP and the P-taps PTAP may be arranged alternately. As described above with reference to FIGS. 1A to 19D, at least some of the first impurity regions N+ may be formed in a jog pattern or jogging pattern, and thus, the first impurity regions N+ may be placed in some regions of the N wells NW and the P wells PW. Accordingly, each N tap NTAP may overlap the N well NW and the P well PW. Similarly, at least some of the second impurity regions P+ may be formed in a jog pattern, and thus, the second impurity regions P+ may be placed in some regions of the N wells NW and the P wells PW. Accordingly, each P-tap PTAP may overlap the N well NW and the P well PW.

In some implementations, at least one of the N taps NTAP and the P-taps PTAP may be placed above a wide nanosheet or a merged nanosheet. In some implementations, at least one of the N taps NTAP and the P-taps PTAP may include a plurality of vias, thereby increasing the via area to reduce via resistance. In some implementations, at least one of the N taps NTAP and the P-taps PTAP may include a long via, thereby increasing the via area to reduce via resistance.

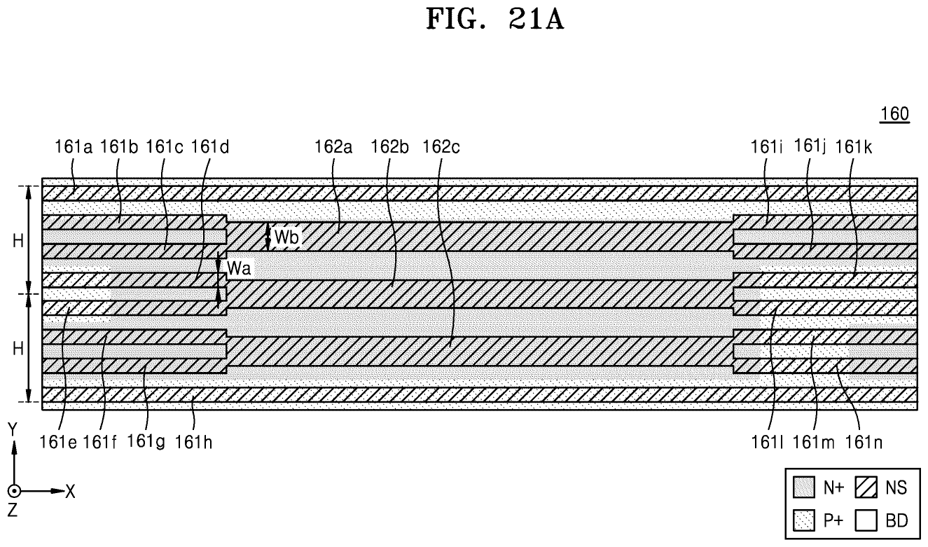

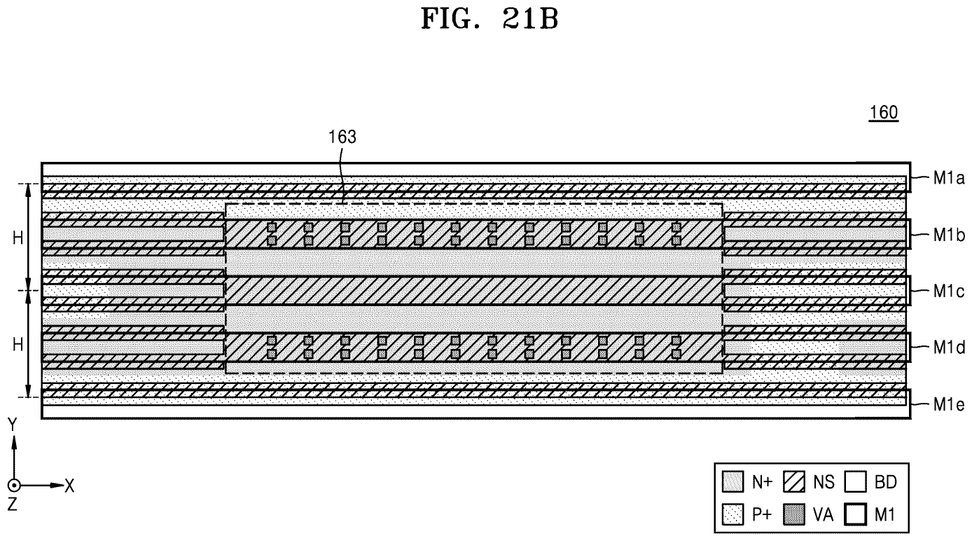

FIGS. 21A and 21B are layout diagrams illustrating an example of a power switch cell 160.

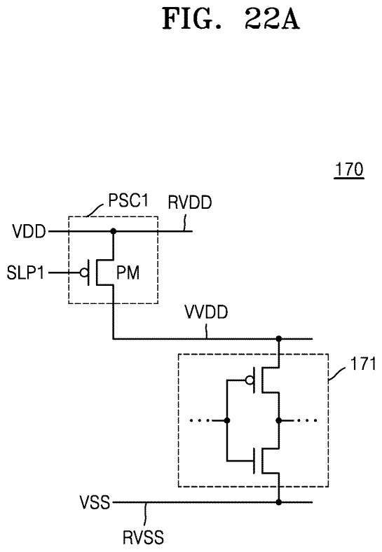

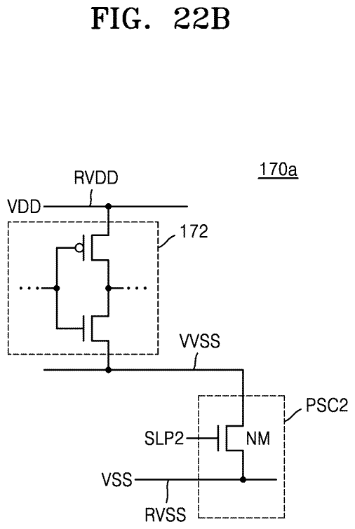

Referring to FIG. 21A, the integrated circuit may include a function cell and a power switch cell 160 adjacent to each other in the first direction X. The function cell may include a plurality of nanosheets, and each of the nanosheets may extend in the first direction X and may have the first width Wa in the second direction Y. The power switch cell 160 may include a switch transistor (e.g., PM of FIG. 22A) between a power line (e.g., RVDD of FIG. 22A) and a virtual power line (e.g., VVDD of FIG. 22A), and the switch transistor may include at least one merged nanosheet 162a to 162c. At least one merged nanosheet 162a to 162c may extend in the first direction X and have the second width Wb in the second direction Y. The switch transistor may selectively provide the power supply voltage to the function cell by selectively connecting the power line to the virtual power line in response to a control signal (e.g., SLP1 in FIG. 22A).

In some implementations, the nanosheets may include a nanosheet stack, the nanosheet stack may include a plurality of normal nanosheets that are apart from each other in the vertical direction Z and each have the first width Wa in the second direction Y, at least one merged nanosheet 162a to 162c may include a merged nanosheet stack, and the merged nanosheet stack may include a plurality of merged nanosheets that are apart from each other in the vertical direction Z and each have the second width Wb in the second direction Y. In some implementations, the second width Wb may be at least twice the first width Wa.

In some implementations, the power switch cell 160 may be defined by the cell boundary BD and may correspond to the double height cell having the second cell height (2×H) in the second direction Y. In some implementations, the power switch cell 160 may be referred to as a ‘power cell’ or a ‘power gating cell’. The power switch cell 160 may include nanosheets NS, and the nanosheets NS may include normal nanosheets 161a to 161n and merged nanosheets 162a to 162c. For example, the merged nanosheets 162a to 162c may be arranged above the N well or the first impurity region N+. Each of the normal nanosheets 161a to 161n may have the first width Wa in the second direction Y, and each of the merged nanosheets 162a to 162c may have the second width Wb that is greater than the first width Wa in the second direction Y. For example, the second width Wb may be twice or more the first width Wa.

The merged nanosheet 162a may be adjacent to the normal nanosheets 161b and 161c in the first direction X and may also be adjacent to the normal nanosheets 161i and 161j in the first direction X. The merged nanosheet 162a may be apart in the second direction Y with respect to the normal nanosheet 161a. The merged nanosheet 162b may be adjacent to the normal nanosheets 161d and 161e in the first direction X and may also be adjacent to the normal nanosheets 161k and 161l in the first direction X. The merged nanosheet 162c may be adjacent to the normal nanosheets 161f and 161g in the first direction X and may also be adjacent to the normal nanosheets 161m and 161n in the first direction X. The merged nanosheet 162c may be apart in the second direction Y with respect to the normal nanosheet 161h.

The merged nanosheets 162a to 162c may constitute a switch transistor (e.g., PM of FIG. 22A) of the power switch cell 160. The switch transistor may be implemented using the merged nanosheets 162a to 162c, thereby improving driving capability or driving strength. Therefore, even if the cell height of the power switch cell 160 is reduced, the performance of the power switch cell 160 may be improved by configuring the switch transistor using the merged nanosheets 162a to 162c.

Referring to FIG. 21B, the power switch cell 160 may further include a switch transistor 163, vias VA, and the first metal layer M1. For convenience of illustration, gate lines GT and contacts CA are not illustrated in FIG. 21B, but the power switch cell 160 may further include gate lines GT and contacts CA, and the merged nanosheets 162a to 162c, the gate lines GT, and the contacts CA may constitute the switch transistor 163.

For example, a source/drain of the switch transistor 163 may receive the power supply voltage VDD from the vias VA connected to the metal patterns M1b and M1d. In some implementations, the switch transistor 163 may be connected to a plurality of vias VA adjacent to each other in the second direction Y. In some implementations, the switch transistor 163 may be connected to long vias extending in the second direction Y. In this manner, by increasing the via area of the switch transistor 163, the via resistance may be reduced.

FIGS. 22A and 22B are circuit diagrams each illustrating an example of an integrated circuit.

Referring to FIG. 22A, the integrated circuit 170 may include a logic circuit 171 and a power gating circuit or power switch circuit PSC1 that provides power to the logic circuit 171. In some implementations, the integrated circuit 170 may be a system-on-chip (SOC). For example, the integrated circuit 170 may be a mobile SOC, an application processor, a media processor, a microprocessor, a central processing unit (CPU), or a similar device.

The power switch circuit PSC1 may be connected to the first power line RVDD that provides the power supply voltage VDD. The power switch circuit PSC1 may control a power mode of the logic circuit 171 by selectively connecting the first power line RVDD to the first virtual power line VVDD in response to the control signal SLP1. The logic circuit 171 may be connected to the first virtual power line VVDD and a second power line RVSS and may receive power through the first virtual power line VVDD and the second power line RVSS. In some implementations, the second power line RVSS may be a ground line, and the logic circuit 171 may receive the ground voltage VSS through the second power line RVSS.

For example, the power switch circuit PSC1 may provide the power supply voltage VDD to the logic circuit 171 by connecting the first power line RVDD to the first virtual power line VVDD in a power-ON mode, and the power switch circuit PSC1 may float the first virtual power line VVDD by disconnecting the first power line RVDD from the first virtual power line VVDD in a power-OFF mode.

The logic circuit 171 may selectively receive power through the first virtual power line VVDD. For example, the logic circuit 171 may be supplied with the power supply voltage VDD in the power-ON mode, and power may be cut off in the power-OFF mode. The logic circuit 171 may include any circuit connected to the first virtual power line VVDD, for example, a plurality of function cells. For example, the logic circuit 171 may be implemented as an inverter, a NAND gate, an AND gate, a NOR gate, an OR gate, an XOR gate, an XNOR gate, a multiplexer, an adder, a latch, a flip-flop, etc.

The power switch circuit PSC1 may include a sleep control transistor or switch transistor PM connected between the first power line RVDD and the first virtual power line VVDD. For example, in the power-ON mode, the switch transistor PM may be turned on in response to a control signal SLP1 having a logic low level, and accordingly, the first virtual power line VVDD may be connected to the first power line RVDD and the power supply voltage VDD may be provided to the logic circuit 171. In the power-OFF mode, the switch transistor PM may be turned off in response to the control signal SLP1 having a logic high level, and thus the first virtual power line VVDD may be disconnected from the first power line RVDD and floated.

In some implementations, the switch transistor PM may be implemented as the switch transistor 163 including the merged nanosheets 162a to 162c of FIGS. 21A and 21B. Each of the merged nanosheets 162a to 162c has the second width Wb in the second direction Y, thereby increasing a channel size of the switch transistor PM and thereby improving driving capability of the switch transistor PM. In addition, a via size above the source/drain connected to the merged nanosheets 162a to 162c may be increased, thereby reducing via resistance. Therefore, the performance of the power switch circuit PSC1 including the switch transistor PM may be improved.

Referring to FIG. 22B, an integrated circuit 170a may include a logic circuit 172 and a power gating circuit or power switch circuit PSC2 that provides power to the logic circuit 172. The power switch circuit PSC2 may be connected to the second power line RVSS that provides the ground voltage VSS. The power switch circuit PSC2 may control a power mode of the logic circuit 172 by selectively connecting the second power line RVSS to the second virtual power line VVSS in response to a control signal SLP2. The logic circuit 172 may be connected to the first power line RVDD and the second virtual power line VVSS and may receive power through the first power line RVDD and the second virtual power line VVSS. In some implementations, the first power line RVDD may be a power line, and the logic circuit 172 may receive the power supply voltage VDD through the first power line RVDD.

For example, the power switch circuit PSC2 may provide the ground voltage VSS to the logic circuit 172 by connecting the second power line RVSS to the second virtual power line VVSS in the power-ON mode, and the power switch circuit PSC2 may float the second virtual power line VVSS by disconnecting the second power line RVSS from the second virtual power line VVSS in the power-OFF mode.

The logic circuit 172 may selectively receive power through the second virtual power line VVSS. For example, the logic circuit 172 may be provided with the ground voltage VSS in the power-ON mode and may be powered off in the power-OFF mode. The logic circuit 172 may include any circuit connected to the second virtual power line VVSS, for example, a plurality of function cells.

The power switch circuit PSC2 may include a sleep control transistor or switch transistor NM connected between the second power line RVSS and the second virtual power line VVSS. For example, in the power-ON mode, the switch transistor NM may be turned on in response to the control signal SLP2 having a logic high level, and accordingly, the second virtual power line VVSS may be connected to the second power line RVSS and the ground voltage VSS may be provided to the logic circuit 172. In the power-OFF mode, the switch transistor NM may be turned off in response to the control signal SLP2 having a logic low level, and thus, the second virtual power line VVSS may be disconnected from the second power line RVSS and floated.

In some implementations, the switch transistor NM may include the merged nanosheets 162a to 162c, such as those illustrated in FIG. 21A and may be formed in the P well PW. Each of the merged nanosheets 162a to 162c may have the second width Wb in the second direction Y, thereby increasing the channel size of the switch transistor NM and thus, thereby improving the driving capability of the switch transistor NM. In addition, the via size above the source/drain connected to the merged nanosheets 162a to 162c may be increased, thereby reducing the via resistance. Therefore, the performance of the power switch circuit PSC2 including the switch transistor NM may be improved.

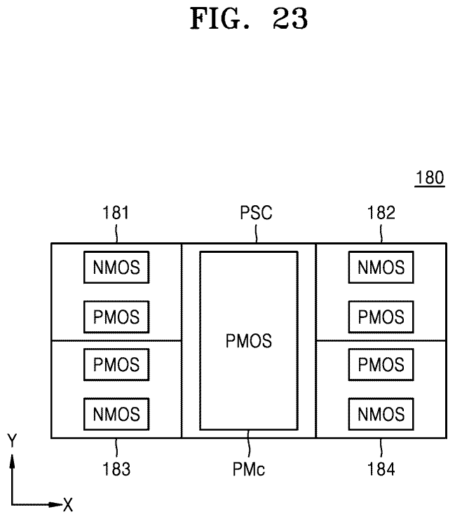

FIG. 23 is a schematic diagram illustrating an example of an integrated circuit 180.

Referring to FIG. 23, the integrated circuit 180 may include first to fourth function cells 181 to 184 and a power switch cell PSC. Each of the first and second function cells 181 and 182 may include an NMOS transistor and a PMOS transistor arranged in the second direction Y, and the NMOS transistor and the PMOS transistor may each include a normal nanosheet (e.g., at least one of 161a to 161n of FIG. 21A) having the first width (e.g., Wa of FIG. 21A). Each of the third and fourth function cells 183 and 184 may include a PMOS transistor and an NMOS transistor arranged in the second direction Y, and the PMOS transistor and the NMOS transistor may each include a normal nanosheet having the first width (e.g., at least one of 161a to 161n of FIG. 21A).

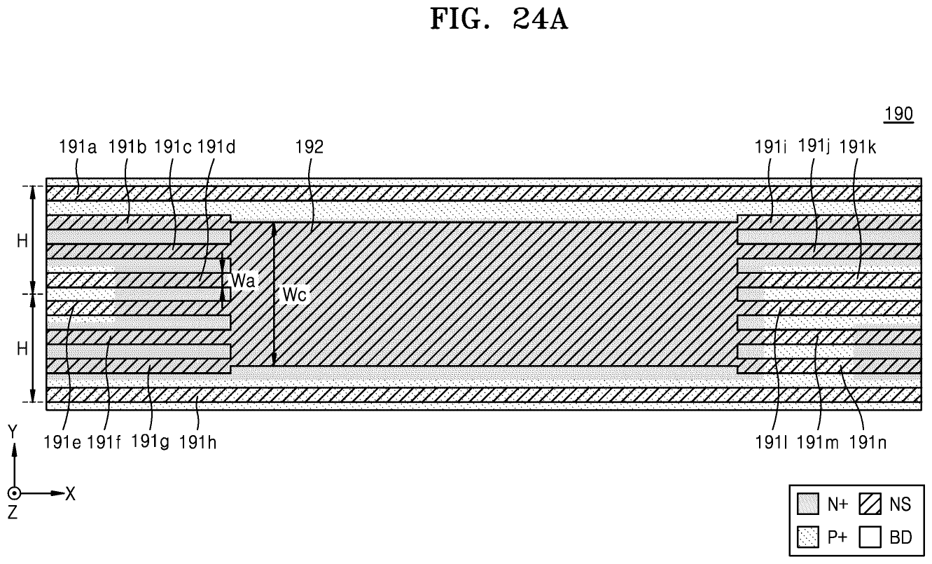

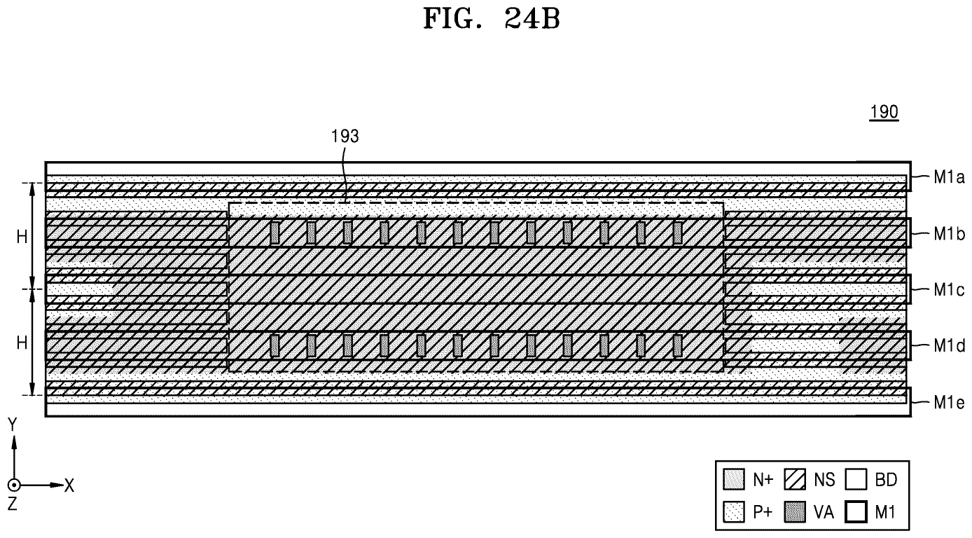

In some implementations, the power switch cell PSC may include a PMOS transistor PMc. For example, the power switch cell PSC may correspond to an example of the power switch circuit PSC1 of FIG. 22A. Here, the PMOS transistor PMc may include a merged nanosheet (e.g., at least one of 162a to 162c in FIG. 21A or 192 in FIG. 24A) having the second width (e.g., Wb in FIG. 21A or Wc in FIG. 24A) that is greater than the first width. Meanwhile, in some implementations, the power switch cell PSC may include an NMOS transistor, and for example, the power switch cell PSC may correspond to an example of the power switch circuit PSC2 of FIG. 22B.

FIGS. 24A and 24B are layout diagrams illustrating an example of a power switch cell 190.

Referring to FIG. 24A, the power switch cell 190 may correspond to a modified example of the power switch cell 160 illustrated in FIGS. 21A and 21B. The power switch cell 190 may include nanosheets NS, and the nanosheets NS may include normal nanosheets 191a to 191n and merged nanosheets 192. The merged nanosheet 192 may be placed above the N well or the first impurity region N+. Each of the normal nanosheets 191a to 191n may have the first width Wa in the second direction Y, and the merged nanosheet 192 may have the second width Wc that is greater than the first width Wa in the second direction Y. For example, the second width Wc may be greater than the second width Wb of FIG. 21A. For example, the second width Wc may be at least three times the first width Wa.

The merged nanosheet 192 may be adjacent to the normal nanosheets 191b to 191g in the first direction X and may also be adjacent to the normal nanosheets 191i to 191n in the first direction X. That is, the merged nanosheet 192 may be arranged between the normal nanosheets 191b to 191g and the normal nanosheets 191i to 191n in the first direction X. The merged nanosheet 192 may be apart in the second direction Y with respect to the normal nanosheet 191a, and may also be apart in the second direction Y with respect to the normal nanosheet 191h. That is, the merged nanosheet 192 may be arranged between the normal nanosheets 191a and 191h in the second direction Y.

The merged nanosheet 192 may constitute a switch transistor (e.g., PM of FIG. 22A) of the power switch cell 190. The switch transistor may be implemented using the merged nanosheet 192 to improve driving capability or driving strength. Therefore, although the cell height of the power switch cell 190 is reduced, the performance of the power switch cell 190 may be improved by configuring the switch transistor using the merged nanosheet 192.

Referring to FIG. 24B, the power switch cell 190 may further include a switch transistor 193, vias VA, and the first metal layer M1. For convenience of illustration, gate lines GT and contacts CA are not illustrated in FIG. 24B, but the power switch cell 190 may further include gate lines GT and contacts CA, and the merged nanosheet 192, gate lines GT and contacts CA may constitute the switch transistor 193.

For example, the source/drain of the switch transistor 193 may receive the power supply voltage VDD from the vias VA connected to the metal patterns M1b and M1d. In some implementations, the switch transistor 193 may be connected to a plurality of vias VA adjacent to each other in the second direction Y. In some implementations, the switch transistor 193 may be connected to long vias extending in the second direction Y. In this manner, by increasing the via area of the switch transistor 193, the via resistance may be reduced.

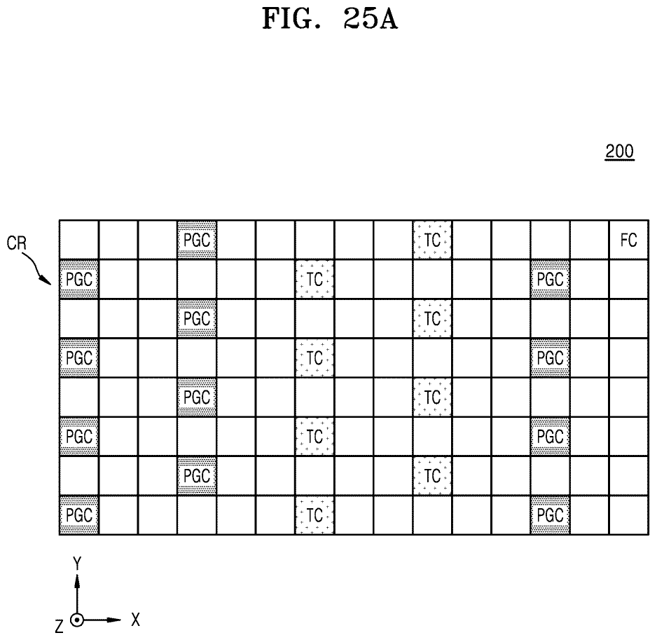

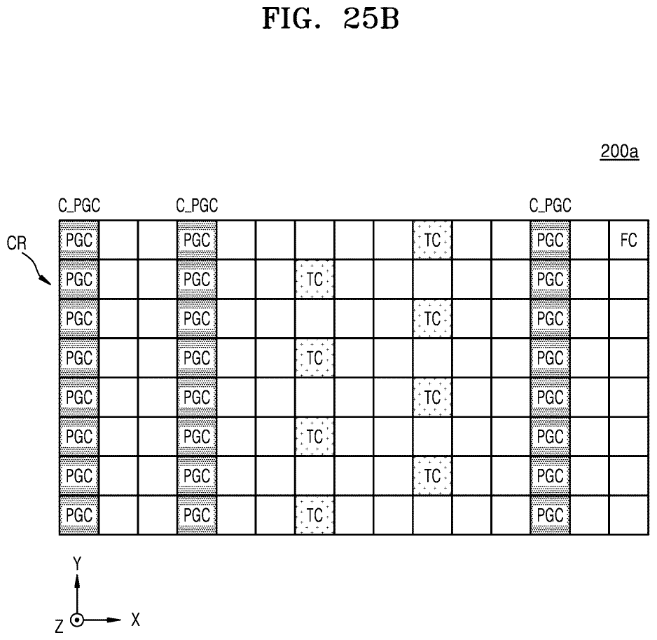

FIGS. 25A and 25B are schematic diagrams respectively illustrating example integrated circuits.

Referring to FIG. 25A, the integrated circuit 200 may include a plurality of cell regions CR, and power switch cells or power gating cells PGC and tap cells TC may be arranged at certain intervals in the cell regions CR. For example, the power gating cell PGC may be the power switch cell described above with reference to FIGS. 21A to 24B. For example, the tap cell TC may be a tap cell described above with reference to FIGS. 1A to 20. In some implementations, the power gating cell PGC may be placed in an odd-numbered cell region CR or an even-numbered cell region CR in the second direction Y, and the tap cell TC may be placed in an odd-numbered cell region CR or an even-numbered cell region CR in the second direction Y. Function cells FC may be placed in the other cell regions CR excluding the power gating cell PGC and the tap cell TC.

Referring to FIG. 25B, an integrated circuit 200a may include a plurality of cell regions CR, and power switch cells or power gating cells PGC and tap cells TC may be arranged at certain intervals in the cell regions CR. For example, the power gating cell PGC may be the power switch cell described above with reference to FIGS. 21A to 24B. For example, the tap cell TC may be the tap cell described above with reference to FIGS. 1A to 20. The power gating cells PGC may be arranged sequentially in the second direction Y, and power gating cells PGC arranged sequentially in the second direction Y may constitute a power gating cell column C_PGC. The tap cell TC may be placed in an odd-numbered cell region CR or an even-numbered cell region CR in the second direction Y. Function cells FC may be placed in the other cell region CR excluding the power gating cell column C_PGC and the tap cell TC.

In FIGS. 25A and 25B, the power gating cell PGC and the tap cell TC are illustrated as single height cells having the same cell height as that of the function cell FC, but other power gating cells PGC and/or tap cells TC according to the technical idea of the present disclosure may include double height cells, quad height cells, octa height cells, etc.

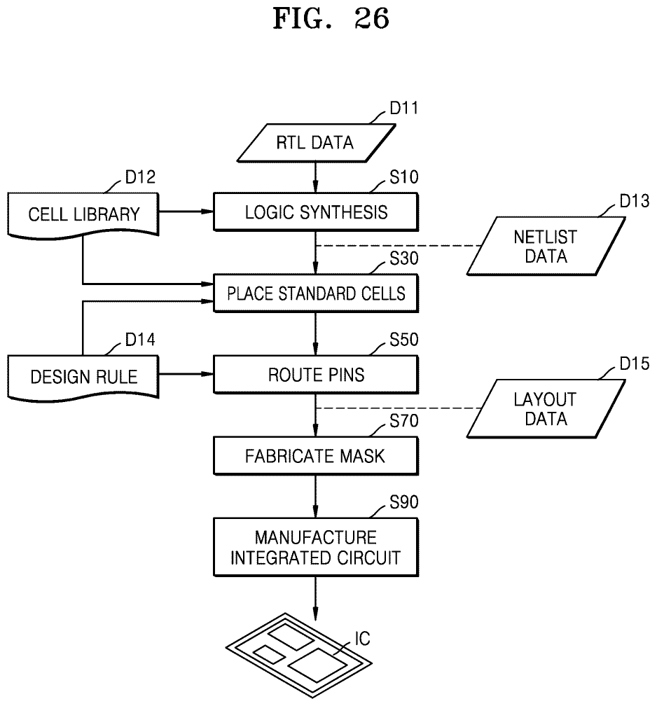

FIG. 26 is a flowchart illustrating an example of a method of manufacturing an integrated circuit,.

Referring to FIG. 26, the method according to the present implementation is a method of manufacturing an integrated circuit including a tap cell including a merged active pattern or merged nanosheet and/or a power switch cell including a merged active pattern or merged nanosheet, which may include a plurality of operations S10, S30, S50, S70, and S90. A cell library (or standard cell library) D12 may include information on standard cells, such as information on their function, characteristics, layout, etc. In some implementations, the cell library D12 may define not only function cells that generate output signals from input signals, but also tap cells, filler cells, power switch cells, and dummy cells. Design rule D14 may include requirements that the layout of an integrated circuit should adhere to. For example, design rule D14 may include requirements for a space between patterns in the same layer, a minimum width of patterns, a routing direction in an interconnection layer, etc.

In operation S10, a logic synthesis operation of generating netlist data D13 from RTL data D11 may be performed. For example, a semiconductor design tool (e.g., a logic synthesis tool) may perform logic synthesis by referencing the cell library D12 from RTL data D11 and generate netlist data D13 including a bitstream or netlist. Netlist data D13 may correspond to input of place and routing described below.

In operation S30, standard cells may be placed. For example, a semiconductor design tool (e.g., a P&R tool) may place standard cells used in netlist data D13 by referencing the cell library D12. In addition, a plurality of bit cells may be arranged. For example, the semiconductor design tool may place bit cells alongside standard cells.

In operation S50, pins of standard cells may be routed. For example, the semiconductor design tool may generate interconnections that electrically connect output pins to input pins of placed standard cells and generate layout data D15 defining the placed standard cells and the generated interconnections. The interconnections may include vias of a via layer and/or patterns of wiring layers. The wiring layers may include a front side wiring layer placed on the front side of a substrate and a back side wiring layer placed on the back side of the substrate. The semiconductor design tool may refer to design rule D14 while routing the pins of cells. Operation S50 alone, or operations S30 and S50 collectively, may be referred to as a method of designing an integrated circuit.

In some implementations, as illustrated in FIGS. 1A to 20, the integrated circuit may include a tap cell including a normal active pattern or normal nanosheet (e.g., nNS of FIG. 1A) having the first width and a merged active pattern or merged nanosheet (e.g., mNS of FIG. 1A) having the second width that is greater than the first width. In some implementations, the tap cell may include a plurality of normal nanosheets overlapping a cell boundary and at least one merged nanosheet within the cell boundary. In some implementations, the normal nanosheets of the tap cell may be connected to adjacent function cell adjacent in the first direction.

In some implementations, as illustrated in FIGS. 21A to 25B, the integrated circuit may include a power switch cell including a normal active pattern or normal nanosheet having the first width (e.g., at least one of 161a to 161n of FIG. 21A) and a merged active pattern or merged nanosheet having the second width that is greater than the first width (e.g., at least one of 162a to 162c of FIG. 21A). In some implementations, the power switch cell may include a plurality of normal nanosheets overlapping the cell boundary and at least one merged nanosheet within the cell boundary. In some implementations, the normal nanosheets of the power switch cell may be connected to adjacent function cell in the first direction.

In operation S70, an operation of fabricating a mask may be performed. For example, optical proximity correction (OPC) to correct a distortion phenomenon, such as refraction, caused by the characteristics of light in photolithography may be applied to layout data D15. Patterns on the mask may be defined to form patterns arranged in a plurality of layers based on data to which OPC is applied, and at least one mask (or photomask) may be fabricated to form the patterns of each of the layers.

In operation S90, an operation of manufacturing an integrated circuit may be performed. For example, the integrated circuit may be manufactured by patterning a plurality of layers using at least one mask fabricated in operation S70. Front-end-of-line (FEOL) may include, for example, operations of planarizing and cleaning a wafer, forming a trench, forming a well, forming a gate line, and forming a source and drain. By means of the FEOL, individual components, such as a transistor, a capacitor, a resistor, etc., may be formed on the substrate. In addition, a back-end-of-line (BEOL) may include operations, such as silicidating gate, source and drain regions, adding a dielectric, planarizing, forming a hole, adding a metal layer, forming a via, forming a passivation layer, etc. By BEOL, individual components, such as transistors, capacitors, resistors, etc. may be interconnected. In some implementations, a middle-of-line (MOL) may be performed between the FEOL and BEOL, and contacts may be formed on individual elements. Thereafter, the integrated circuit may be packaged into a semiconductor package and used as a component in a variety of applications.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it is understood that various changes in form and details may be made therein without departing from the spirit and scope of the following claims.

What is claimed is:

1. An integrated circuit comprising:
a function cell; and
a tap cell adjacent to the function cell in a first direction,
wherein the function cell comprises:
a plurality of nanosheets, each nanosheet of the plurality of nanosheets extending in the first direction and having a first width in a second direction intersecting the first direction,
wherein the tap cell comprises:
a first well having a first conductivity type;
at least one merged nanosheet extending in the first direction, the at least one merged nanosheet having a second width in the second direction, the second width being greater than the first width; and
at least one first via configured to apply a first supply voltage to the first well.

2. The integrated circuit of claim 1, wherein the tap cell comprises at least one normal nanosheet, the at least one normal nanosheet extending in the first direction and having the first width in the second direction.

3. The integrated circuit of claim 2, wherein
the at least one normal nanosheet includes a first normal nanosheet and a second normal nanosheet, the first normal nanosheet and the second normal nanosheet being apart from each other in the second direction, and
the at least one merged nanosheet includes a first merged nanosheet, the first merged nanosheet being adjacent to the first normal nanosheet and the second normal nanosheet in the first direction.

4. The integrated circuit of claim 3, wherein
the at least one normal nanosheet includes a third normal nanosheet and a fourth normal nanosheet, the third normal nanosheet and the fourth normal nanosheet being apart from each other in the second direction,
the at least one merged nanosheet is between the first and second normal nanosheets and the third and fourth normal nanosheets in the first direction, and
the first merged nanosheet, the first normal nanosheet, the second normal nanosheet, the third normal nanosheet, and the fourth normal nanosheet are in an I-shape.

5. The integrated circuit of claim 3, wherein the at least one normal nanosheet includes:
a fifth normal nanosheet apart from the first normal nanosheet and the first merged nanosheet in the second direction; and
a sixth normal nanosheet apart from the second normal nanosheet and the first merged nanosheet in the second direction,
wherein the first merged nanosheet is between the fifth normal nanosheet and the sixth normal nanosheet in the second direction.

6. The integrated circuit of claim 5, wherein
the at least one merged nanosheet includes a second merged nanosheet adjacent to the fifth normal nanosheet in the first direction,
the at least one normal nanosheet includes a seventh normal nanosheet adjacent to the second merged nanosheet in the first direction,
the second merged nanosheet is between the fifth normal nanosheet and the seventh normal nanosheet in the first direction, and
the second merged nanosheet and the fifth and seventh normal nanosheets have a T shape.

7. The integrated circuit of claim 2, wherein
the at least one normal nanosheet includes a nanosheet stack,
the nanosheet stack includes a plurality of normal nanosheets, the plurality of normal nanosheets being apart from each other in a vertical direction and each normal nanosheet of the plurality of normal nanosheets having the first width in the second direction, and
the at least one merged nanosheet includes a merged nanosheet stack,
the merged nanosheet stack includes a plurality of merged nanosheets, the plurality of merged nanosheets being apart from each other in the vertical direction and each merged nanosheet of the plurality of merged nanosheets having the second width in the second direction.

8. The integrated circuit of claim 1, wherein the tap cell comprises a first impurity region having the first conductivity type, and
wherein the at least one first via is above the first well and the first impurity region, and the at least one first via is configured to provide the first supply voltage to the first impurity region and the first well.

9. The integrated circuit of claim 1, wherein the tap cell comprises at least one second via configured to apply a second supply voltage to a second well or a substrate, the second well or the substrate having a second conductivity type different from the first conductivity type.

10. The integrated circuit of claim 9, wherein the tap cell comprises a second impurity region having the second conductivity type, and
wherein the at least one second via is above the second well and the second impurity region, and the at least one second via is configured to provide the second supply voltage to the second impurity region and the second well.

11. The integrated circuit of claim 9, wherein the at least one first via corresponds to a well tap and the at least one second via corresponds to a substrate tap.

12. The integrated circuit of claim 1, wherein
the at least one first via is above a front side of a substrate,
the tap cell comprises a first metal layer above the at least one first via, and
the at least one first via is configured to
receive the first supply voltage from the first metal layer, and
provide the received first supply voltage to the first well.

13. The integrated circuit of claim 1, wherein
the tap cell comprises a back side metal layer on a back side of a substrate,
the at least one first via includes a back side contact that extends into the substrate in a vertical direction, and
the back side contact is configured to
receive the first supply voltage from the back side metal layer, and
provide the received first supply voltage to the first well.

14. The integrated circuit of claim 1, wherein the tap cell corresponds to a multi-height cell positioned across a plurality of rows.

15. An integrated circuit comprising:
a function cell including a plurality of nanosheets, each nanosheet of the plurality of nanosheets extending in a first direction and having a first width in a second direction intersecting the first direction; and
a power switch cell adjacent to the function cell in the first direction,
wherein the power switch cell comprises a switch transistor between a power line and a virtual power line, and
wherein the switch transistor includes at least one merged nanosheet, the at least one merged nanosheet extending in the first direction and having a second width in the second direction, the second width being greater than the first width, and
wherein the switch transistor is configured to selectively connect the power line with the virtual power line based on a control signal to selectively provide a power supply voltage to the function cell.

16. The integrated circuit of claim 15, wherein
the plurality of nanosheets include a nanosheet stack,
the nanosheet stack includes a plurality of normal nanosheets, the plurality of normal nanosheets being apart from each other in a vertical direction, and each normal nanosheet of the plurality of normal nanosheets having the first width in the second direction,
the at least one merged nanosheet includes a merged nanosheet stack, and
the merged nanosheet stack includes a plurality of merged nanosheets, the plurality of merged nanosheets being apart from each other in the vertical direction and each merged nanosheet of the plurality of merged nanosheets having the second width in the second direction.

17. The integrated circuit of claim 15, wherein the second width is at least twice the first width.

18. An integrated circuit comprising:
a function cell; and
a tap cell adjacent to the function cell in a first direction,
wherein the function cell comprises:
a P-type transistor including a first active pattern, the first active pattern extending in the first direction and having a first width in a second direction intersecting the first direction; and
an N-type transistor including a second active pattern, the second active pattern extending in the first direction and having the first width in the second direction, and the N-type transistor being apart from the P-type transistor in the second direction, and
wherein the tap cell comprises:
at least one merged active pattern extending in the first direction and having a second width in the second direction, the second width being greater than the first width; and
at least one tap above the at least one merged active pattern,
wherein the at least one tap includes at least one via configured to apply a supply voltage to a well or a substrate.

19. The integrated circuit of claim 18, wherein the tap cell comprises a plurality of active patterns, each active pattern of the plurality of active patterns extending in the first direction and having the first width in the second direction.

20. The integrated circuit of claim 19, wherein
each active pattern of the plurality of active patterns includes a nanosheet stack,
the nanosheet stack includes a plurality of normal nanosheets, the plurality of normal nanosheets being apart from each other in a vertical direction and each normal nanosheet the plurality of normal nanosheets having the first width in the second direction,
the at least one merged active pattern includes a merged nanosheet stack, and
the merged nanosheet stack includes a plurality of merged nanosheets, the plurality of merged nanosheets being apart from each other in the vertical direction and each merged nanosheet of the plurality of merged nanosheets having the second width in the second direction.
